(19) United States
(12) Patent Application Publication
(10) Pub. No.: US 2025/0382703 A1
(43) Pub. Date: Dec. 18, 2025

(54) PLASMA ENHANCED LOW TEMPERATURE ATOMIC LAYER DEPOSITION OF METALS

(71) Applicant: Lam Research Corporation, Fremont, CA (US)

(72) Inventors: Alexander Ray Fox, Portland, OR (US); Elham Mohimi, Tigard, OR (US); Jon Henri, West Linn, OR (US); Ann Erickson, Lake Oswego, OR (US); Chiukin Steven Lai, Sunnyvale, CA (US); Patrick August van Cleemput, Castle Rock, WA (US); Kyle Jordan Blakeney, Milpitas, CA (US); David Joseph Mandia, Lake Oswego, OR (US)

(21) Appl. No.: 18/877,501

(22) PCT Filed: Jun. 23, 2023
(86) PCT No.: PCT/US2023/069018

§ 371 Date: Dec. 20, 2024

Related U.S. Application Data
(60) Provisional application No. 63/366,888, filed on Jun. 23, 2022.

(51) Int. Cl. C23C 16/455; C23C 16/02; C23C 16/52

(52) U.S. Cl. CPC C23C 16/45536; C23C 16/0245; C23C 16/45544; C23C 16/45553; C23C 16/52

(57) ABSTRACT

Provided are reduced-temperature plasma enhanced atomic layer deposition processes including application of a thin metal layer by contacting a substrate surface at temperatures of 300° C. or lower with a metal precursor and a plasma of a hydrogen-containing gas source generated directly or remotely.

### INCORPORATION BY REFERENCE

A PCT Request Form is filed concurrently with this specification as part of the present application. Each application that the present application claims benefit of or priority to as identified in the concurrently filed application PCT Request Form is incorporated by reference herein in their entireties and for all purposes.

### BACKGROUND

Many semiconductor device fabrication processes involve deposition of metals such as molybdenum or copper to form ultra-thin conductive films. Plasma enhanced atomic layer deposition (ALD) may be utilized to deposit metal-containing films. The morphology of the films is a consideration in designing such a process for ultra-thin conductive film preparation, as a rough morphology may lead to elevated film resistivity and may be associated with voids in the conductive fill metal and pinch-off of fill metal in features.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided are reduced-temperature plasma enhanced atomic layer deposition processes including application of a thin metal layer by contacting a substrate surface at temperatures of 300° C. or lower with a metal precursor and a plasma of a hydrogen-containing gas source generated directly or remotely.

Accordingly, in a first aspect, the present invention encompasses a method for plasma-enhanced atomic layer deposition of a thin metal film on a surface of a substrate. In some embodiments, the method includes providing the substrate in a deposition chamber, wherein the substrate is at a temperature of about 300° C. or less; exposing a surface of the substrate to a vapor phase metal precursor; and exposing the substrate to plasma generated directly or plasma generated remotely from a hydrogen-containing gas source.

In some embodiments, the metal is vanadium, niobium, tantalum, chromium, cobalt, tungsten, iron, ruthenium, nickel, zinc, copper or molybdenum.

In some embodiments, the vapor phase metal precursor is a vanadium-containing precursor, niobium-containing precursor, tantalum-containing precursor, chromium-containing precursor, cobalt-containing precursor, tungsten-containing precursor, iron-containing precursor, ruthenium-containing precursor, nickel-containing precursor, zinc-containing precursor, copper-containing precursor or molybdenum-containing precursor.

In some embodiments, exposing the surface of the substrate to the vapor phase metal precursor and exposing the substrate to plasma generated remotely from a hydrogen-containing gas source are performed in temporally separate pulses.

In some embodiments, the vapor phase metal precursor adsorbs onto the surface of the substrate to form an adsorbed metal precursor.

In some embodiments, the plasma generated remotely from a hydrogen-containing gas source converts the adsorbed metal precursor to elemental metal.

In some embodiments, the method also includes pre-treating the surface of the substrate with plasma generated remotely from a hydrogen-containing gas source before exposing the surface of the substrate to a vapor phase metal precursor.

In some embodiments, the hydrogen-containing gas source further includes about 0.01% to about 1% of oxygen-containing gas.

In some embodiments, the plasma is an inductively coupled plasma or a capacitively coupled plasma.

In some embodiments, the oxygen-containing gas is oxygen, oxygen and argon, oxygen and helium, ozone or a combination thereof.

In some embodiments, the hydrogen-containing gas source is a gas such as hydrogen, deuterium, hydrogen and argon, hydrogen and helium, hydrogen and nitrogen, ammonia, singly deuterated ammonia, doubly deuterated ammonia, triply deuterated ammonia, hydrazine, an alcohol, an aldehyde or a combination thereof.

In some embodiments, the oxygen-containing gas is delivered at a flow rate of about 1 to about 150 sccm.

In a second aspect, the present disclosure encompasses a method for plasma-enhanced atomic layer deposition of molybdenum on a substrate including: providing a substrate in a deposition chamber, wherein the substrate is at a temperature of about 300° C. or less; exposing a surface of the substrate to a vapor phase molybdenum precursor, and exposing the substrate to plasma generated directly or plasma generated remotely from a hydrogen-containing gas source.

In some embodiments, the method also includes a pre-treatment of the surface of the substrate with plasma generated remotely from a hydrogen-containing gas source before exposing the surface of the substrate to a vapor phase molybdenum precursor.

In some embodiments, the vapor phase molybdenum precursor has the structure of formula (I): Mo(L-R¹)₆ wherein each L is independently O, S or NR²; and R¹ and R² are independently hydrogen, optionally substituted aliphatic, optionally substituted heteroaliphatic, optionally substituted heteroaromatic, optionally substituted heteroaryl, optionally substituted heterocyclyl, optionally substituted aromatic, optionally substituted aryl, or optionally substituted arylalkylene; and wherein two R¹ substituents can be taken together to form an optionally substituted cyclic group.

In some embodiments, the vapor phase molybdenum precursor has the structure of formula (II): Mo(L-R¹)₂(Y)₄ wherein each L is independently O, S, or NR²; R¹ and R² are independently hydrogen, optionally substituted aliphatic, optionally substituted alkyl, optionally substituted heteroaliphatic, optionally substituted heteroalkyl, optionally substituted heteroaromatic, optionally substituted heteroaryl, optionally substituted heterocyclyl, optionally substituted aromatic, optionally substituted aryl, or optionally substituted arylalkylene; and wherein R¹ substituents can be taken together to form an optionally substituted cyclic group; and each Y is independently chlorine, fluorine, bromine or iodine.

In some embodiments, the vapor phase molybdenum precursor is MO_{q}XₙYₘ, wherein X is oxygen, Y is a halogen, n is 0, 1, or 2; q is 1 or 2; and m is 2, 3, 4, 5, or 6.

In some embodiments, the vapor phase molybdenum precursor is molybdenum pentachloride (MoCl₅), molybdenum (V) chloride (Mo₂Cl₁₀), molybdenum (VI) dichloride dioxide (MoO₂Cl₂), molybdenum oxytetrachloride (MoOCl₄) or any combination thereof.

In some embodiments, exposing the surface of the substrate to the vapor phase molybdenum precursor and exposing the substrate to plasma generated remotely from a hydrogen-containing gas source are performed in temporally separate pulses.

In some embodiments, the vapor phase molybdenum precursor adsorbs onto the surface of the substrate to form an adsorbed molybdenum precursor.

In some embodiments, the plasma generated remotely from a hydrogen-containing gas source converts the adsorbed molybdenum precursor to elemental molybdenum.

In some embodiments, the hydrogen-containing gas source also includes about 0.01% to about 1% of oxygen-containing gas.

In some embodiments, the plasma is an inductively coupled plasma or a capacitively coupled plasma.

In some embodiments, the oxygen-containing gas is oxygen, oxygen and argon, oxygen and helium, ozone or a combination thereof.

In some embodiments, the hydrogen-containing gas source is a gas such as hydrogen, deuterium, hydrogen and argon, hydrogen and helium, hydrogen and nitrogen, ammonia, singly deuterated ammonia, doubly deuterated ammonia, triply deuterated ammonia, hydrazine, an alcohol, an aldehyde or a combination thereof.

In some embodiments, the oxygen-containing gas is delivered at a flow rate of about 1 to about 150 sccm.

In a third aspect, the present disclosure encompasses a method for controlling morphology of copper deposited on a substrate by plasma-enhanced atomic layer deposition including providing a substrate in a deposition chamber, wherein the substrate is at a temperature of about 300° C. or less; exposing a surface of the substrate to a vapor phase copper precursor; and exposing the substrate to plasma generated remotely from a gas source, wherein the gas source comprises a hydrogen-containing gas and from about 0.01% to about 1% of oxygen-containing gas.

In some embodiments, the method also includes pre-treatment of the surface of the substrate with plasma generated remotely from a hydrogen-containing gas source before exposing the surface of the substrate to a vapor phase copper precursor.

In some embodiments, the vapor phase copper precursor has the structure of formula:

Cu(L-R³)ₙ, Cu₂(B)₂, or Cu₄(N(R⁴)₂)₄ wherein each L is independently O, NR⁴ or P(R⁵)₃; B is a bidentate ligand; R³, R⁴ and R⁵ are each independently hydrogen, optionally substituted aliphatic, optionally substituted heteroaliphatic, optionally substituted heteroaromatic, optionally substituted heteroaryl, optionally substituted heterocyclyl, optionally substituted aromatic, optionally substituted aryl, trimethylsilyl, or optionally substituted arylalkylene; n is an integer of 2 or 4; wherein when n is 4, two R³ substituents can be taken together to form an optionally substituted cyclic group; and wherein copper is optionally coordinated to an optionally substituted alkenyl, optionally substituted alkynyl, carbonyl, aryl or heteroaryl containing compound.

In some embodiments, the vapor phase copper precursor is a cuprous precursor.

In some embodiments, the cuprous precursor is an acetylacetonate, ketoiminate, diiminate, cyclopentadienyl, amidinate, guanidinate or amide compound.

In some embodiments, the vapor phase copper precursor is a cupric precursor.

In some embodiments, the cupric precursor is an acetylacetonate, ketoiminate or aminoalkoxide compound.

In some embodiments, the plasma is an inductively coupled plasma or a capacitively coupled plasma.

In some embodiments, the oxygen-containing gas is oxygen, oxygen and argon, oxygen and helium, ozone or a combination thereof.

In some embodiments, the hydrogen-containing gas source is a gas such as hydrogen, deuterium, hydrogen and argon, hydrogen and helium, hydrogen and nitrogen, ammonia, singly deuterated ammonia, doubly deuterated ammonia, triply deuterated ammonia, hydrazine, an alcohol, an aldehyde or a combination thereof.

In some embodiments, exposing the surface of the substrate to the vapor phase copper precursor and exposing the substrate to plasma generated remotely from a hydrogen-containing gas source are performed in temporally separate pulses.

In some embodiments, the vapor phase copper precursor adsorbs onto the surface of the substrate to form an adsorbed copper precursor.

In some embodiments, the plasma generated remotely from a hydrogen-containing gas source converts the adsorbed copper precursor to elemental copper.

In some embodiments, the oxygen-containing gas is delivered at a flow rate of about 1 to about 150 sccm.

In a fourth aspect, the present disclosure encompasses an apparatus for depositing a thin metal film on a substrate, the apparatus including: at least one reaction chamber including a pedestal for holding a substrate; at least one inlet port for delivering gas phase metal precursors to the reaction chamber, a direct plasma generator or a remote plasma generator for providing plasma to the reaction chamber, and a controller for controlling operations in the apparatus, including machine-readable instructions for (a) causing the substrate temperature to be at about 300° C. or less; (b) causing introduction of a metal precursor in vapor phase into the at least one reaction chamber, and (c) causing introduction of a plasma from the direct plasma generator or the remote plasma generator to form the thin metal film over the substrate, the plasma generated from a hydrogen-containing gas and from about 0.01% to about 1% of oxygen-containing gas.

These and other aspects are discussed further below with reference to the drawings.

### BRIEF DESCRIPTION OF DRAWINGS

FIG. 1 is a process flow diagram depicting operations for methods of thin metal film deposition in accordance with certain disclosed embodiments.

FIG. 2 is a depiction of various cuprous precursors for methods of thin metal film deposition in accordance with certain disclosed embodiments.

FIG. 3 is a depiction of various cupric precursors for methods of thin metal film deposition in accordance with certain disclosed embodiments.

FIG. 4 is a depiction of various ligands for molybdenum precursors for methods of thin metal film deposition in accordance with certain disclosed embodiments.

FIG. 5 is a depiction of various ligands for molybdenum precursors for methods of thin metal film deposition in accordance with certain disclosed embodiments.

FIG. 6 is a depiction of various molybdenum precursors for methods of thin metal film deposition in accordance with certain disclosed embodiments.

FIG. 7 shows an example of the apparatus with remote plasma source that may be used to perform the methods described herein in accordance with certain disclosed embodiments.

FIG. 8 is a schematic diagram of an example plasma processing apparatus for performing the methods in accordance with certain disclosed embodiments.

FIG. 9A is a graphical comparison the thickness of copper deposited with and without added oxygen in the remotely generated plasm hydrogen-containing gas source in accordance with certain disclosed embodiments.

FIG. 9B is a graphical representation of the thickness of copper deposited at various oxygen flow rates into the remotely generated plasm hydrogen-containing gas source accordance with certain disclosed embodiments.

FIG. 9C is a graphical representation of the resistivity of copper deposited when various oxygen flow rates are fed into the remotely generated plasm hydrogen-containing gas source in accordance with certain disclosed embodiments.

FIG. 10 illustrates scanning electron microscopy images of copper deposited in accordance with the method, depicting variations in morphology with different oxygen gas flow rates, as added to hydrogen gas in the plasma generated from a remote plasma source in accordance with certain disclosed embodiments.

FIG. 11A is a scanning transmission electron microscopy (STEM) image of copper deposition onto a feature of a substrate surface when a remotely generated plasma of a hydrogen-containing gas source without added oxygen is utilized in accordance with certain disclosed embodiments.

FIG. 11B is a scanning transmission electron microscopy (STEM) image of copper deposition with less roughness onto a feature of a substrate surface when a remotely generated plasma of a hydrogen-containing gas source including 20 sccm added oxygen is utilized in accordance with certain disclosed embodiments.

FIG. 12 is a graphical comparison of the thickness of molybdenum deposited at substrate temperatures above and below 300° C. utilizing MoCl₅ as the molybdenum precursor in accordance with certain disclosed embodiments.

### DETAILED DESCRIPTION

### Definitions

“Heteroleptic complexes”, as used herein, refer to compounds that contain at least two different ligands attached to a metal center.

“Homoleptic complexes”, as used herein, refer to compounds that contain all identical ligands attached to a metal center.

As used herein, the term “about” means+/−10% of any recited value, unless otherwise specified. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

As used herein, the phrase at least one of A, B, and C should be construed to mean a logical (A OR B OR C), using a non-exclusive logical OR, and should not be construed to mean ‘at least one of A, at least one of B, and at least one of C.

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl (—C(O)H), acetyl (Ac or —C(O)Me), propionyl, isobutyryl, butanoyl, and the like. In some embodiments, the acyl or alkanoyl group is —C(O)—R, in which R is hydrogen, an aliphatic group, or an aromatic group, as defined herein.

By “alkanoyloxy” is meant an alkanoyl group, as defined herein, attached to the parent molecular group through an oxy group, as defined herein. This group is exemplified by acetoxy (—OAc or —OC(O)Me). In some embodiments, the alkanoyloxy group is —OC(O)—R, in which R is hydrogen, an aliphatic group, or an aromatic group, as defined herein.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “aliphatic-carbonyl” is meant an aliphatic group that is or can be coupled to a compound disclosed herein, wherein the aliphatic group is or becomes coupled through a carbonyl group (—C(O)—). In some embodiments, the aliphatic-carbonyl group is —C(O)—R, in which R is an optionally substituted aliphatic group, as defined herein.

By “aliphatic-carbonyloxy” is meant an aliphatic group that is or can be coupled to a compound disclosed herein, wherein the aliphatic group is or becomes coupled through a carbonyloxy group (—OC(O)—). In some embodiments, the aliphatic-carbonyloxy group is —OC(O)—R, in which R is an optionally substituted aliphatic group, as defined herein.

By “aliphatic-oxy” is meant an aliphatic group that is or can be coupled to a compound disclosed herein, wherein the aliphatic group is or becomes coupled through an oxy group. In some embodiments, the aliphatic-oxy group is —O—R, in which R is an optionally substituted aliphatic group, as defined herein.

By “aliphatic-oxycarbonyl” is meant an aliphatic group that is or can be coupled to a compound disclosed herein, wherein the aliphatic group is or becomes coupled through an oxycarbonyl group (—C(O)O—). In some embodiments, the aliphatic-oxycarbonyl group is —C(O)O—R, in which R is an optionally substituted aliphatic group, as defined herein.

By “alkyl-aryl,” “alkenyl-aryl,” and “alkynyl-aryl” is meant an alkyl, alkenyl, or alkynyl group, respectively and as defined herein, that is or can be coupled (or attached) to the parent molecular group through an aryl group, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl and/or aryl. Exemplary unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Exemplary unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Exemplary unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is -L-R, in which L is an aryl group or an arylene group, as defined herein, and R is an alkyl group, as defined herein. In some embodiments, the alkenyl-aryl group is -L-R, in which L is an aryl group or an arylene group, as defined herein, and R is an alkenyl group, as defined herein. In some embodiments, the alkynyl-aryl group is -L-R, in which L is an aryl group or an arylene group, as defined herein, and R is an alkynyl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl. Non-limiting alkenyl groups include allyl (All), vinyl (Vi), 1-butenyl, 2-butenyl, and the like.

By “alkoxy” is meant —OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁-1₆, C₁-1₈, C₁₋₂₀, or C₁₋₂₄ alkoxy groups.

By “alkoxyalkyl” is meant an alkyl group, as defined herein, which is substituted with an alkoxy group, as defined herein. Exemplary unsubstituted alkoxyalkyl groups include between 2 to 12 carbons (C₂₋₁₂ alkoxyalkyl), as well as those having an alkyl group with 1 to 6 carbons and an alkoxy group with 1 to 6 carbons (i.e., C₁₋₆ alkoxy-C₁₋₆ alkyl). In some embodiments, the alkoxyalkyl group is -L-O—R, in which each of L and R is, independently, an alkyl group, as defined herein.

By “alkoxycarbonyl” is meant —C(O)—OR, where R is an optionally substituted aliphatic group, as described herein. In particular embodiments, the alkoxycarbonyl group is —C(O)—OAk, in which Ak is an alkyl group, as defined herein. The alkoxycarbonyl group can be substituted or unsubstituted. For example, the alkoxycarbonyl group can be substituted with one or more substitution groups, as described herein for alkyl. Exemplary unsubstituted alkoxycarbonyl groups include C₂₋₃, C₂₋₆, C₂₋₇, C₂₋₁₂, C₂₋₁₆, C₂₋₁₈, C₂₋₂₀, or C₂₋₂₄ alkoxycarbonyl groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl (Me), ethyl (Et), n-propyl (nPr), iso-propyl (iPr), n-butyl (nBu), iso-butyl (iBu), sec-butyl (sBu), tert-butyl (tBu), pentyl (Pe), n-pentyl (nPe), isopentyl (iPe), s-pentyl (sPe), neopentyl (neoPe), tert-pentyl (tPe), hexyl (Hx), heptyl (Hp), octyl (Oc), nonyl (Nn), decyl (De), dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17)N-protected amino; (18) nitro (e.g., —NO₂); (19) oxo (e.g., ═O); (20) C₁₋₆ thioalkyl (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄-s aryl, and (c) C₄₋₁₈ aryl-C₁₋₆ alkyl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene,” “alkenylene,” or “alkynylene” is meant a multivalent (e.g., bivalent) form of an alkyl, alkenyl, or alkynyl group, respectively, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₂, C₂₋₂₀, or C₂₋₂₄ alkylene group. In other embodiments, the alkylene group is a C₂₋₃, C₂₋₄, C₂₋₁₂, C₂₋₁₆, C₂₋₁₈, C₂₋₂₀, or C₂₋₂₄ alkenylene or alkynylene group. The alkylene, alkenylene, or alkynylene group can be branched or unbranched. The alkylene, alkenylene, or alkynylene group can also be substituted or unsubstituted. For example, the alkylene, alkenylene, or alkynylene group can be substituted with one or more substitution groups, as described herein for alkyl.

By “alkylsultinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfinylalkyl” is meant an alkyl group, as defined herein, substituted by an alkylsulfinyl group. In some embodiments, the unsubstituted alkylsulfinylalkyl group is a C₂₋₁₂ or C₂₋₂₄ alkylsulfinylalkyl group (e.g., C₁₋₆ alkylsulfinyl-C₁₋₆ alkyl or C₁₋₁₂ alkylsulfinyl-C₁₋₁₂ alkyl). In other embodiments, the alkylsulfinylalkyl group is -L-S(O)—R, in which each of L and R is, independently, an alkyl group, as defined herein.

By “alkylsulfonyl” is meant an alkyl group, as defined herein, attached to the parent molecular group through an —SO₂— group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkylsulfonylalkyl” is meant an alkyl group, as defined herein, substituted by an alkylsulfonyl group. In some embodiments, the unsubstituted alkylsulfonylalkyl group is a C₂₋₁₂ or C₂₋₂₄ alkylsulfonylalkyl group (e.g., C₁₋₆ alkylsulfonyl-C₁₋₆ alkyl or C₁₋₁₂ alkylsulfonyl-C₁₋₁₂ alkyl). In other embodiments, the alkylsulfonylalkyl group is -L-SO₂—R, in which each of L and R is, independently, an alkyl group, as defined herein.

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “ambient temperature” is meant a temperature ranging from 16° C. to 26° C., such as from 19° C. to 25° C. or from 20° C. to 25° C.

By “amide” is mean —C(O)NR¹R² or —NHCOR¹, where each of R¹ and R² is, independently, selected from hydrogen, aliphatic, heteroaliphatic, aromatic, as defined herein, or any combination thereof, or where R¹ and R², taken together with the nitrogen atom to which each are attached, can form a heterocyclyl group, as defined herein.

By “amino” is meant —NR¹R², where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R¹ and R² can be taken together, with the nitrogen atom to which each is attached, to form an optionally substituted heterocyclyl.

By “aminoalkyl” is meant an alkyl group, as defined herein, substituted by an amino group, as defined herein. In some embodiments, the aminoalkyl group is -L-NR¹R², in which L is an alkyl group, as defined herein, and each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein; and each of R³ and R⁴ is, independently, H or alkyl, as defined herein.

By “aminooxy” is meant an oxy group, as defined herein, substituted by an amino group, as defined herein. In some embodiments, the aminooxy group is —O—NR¹R², in which each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system. An aromatic group is unsubstituted or substituted, e.g., by a functional group described herein. For example, the aromatic group can be substituted with one or more substitution groups, as described herein for alkyl and/or aryl.

By “aromatic-carbonyl” is meant an aromatic group that is or can be coupled to a compound disclosed herein, wherein the aromatic group is or becomes coupled through a carbonyl group (—C(O)—). In some embodiments, the aromatic-carbonyl group is —C(O)—R, in which R is an optionally substituted aromatic group, as defined herein.

By “aromatic-carbonyloxy” is meant an aromatic group that is or can be coupled to a compound disclosed herein, wherein the aromatic group is or becomes coupled through a carbonyloxy group (—OC(O)—). In some embodiments, the aromatic-carbonyloxy group is —OC(O)—R, in which R is an optionally substituted aromatic group, as defined herein.

By “aromatic-oxy” is meant an aromatic group that is or can be coupled to a compound disclosed herein, wherein the aromatic group is or becomes coupled through an oxy group (—O—). In some embodiments, the aromatic-oxy group is —O—R, in which R is an optionally substituted aromatic group, as defined herein.

By “aromatic-oxycarbonyl” is meant an aromatic group that is or can be coupled to a compound disclosed herein, wherein the aromatic group is or becomes coupled through an oxycarbonyl group (—C(O)O—). In some embodiments, the aromatic-carbonyl group is —C(O)O—R, in which R is an optionally substituted aromatic group, as defined herein.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -L-SO₂—R, in which each of L and R is, independently, C₁₋₆ alkyl); (9) aryl; (10) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein); (11) C₁₋₆ aminoalkyl (e.g., -L¹-NR¹R² or -L²-C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein; and each of R³ and R⁴ is, independently, H or C₁₋₆ alkyl); (12) heteroaryl; (13) C₄₋₁₈ aryl-C₁₋₆ alkyl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆ azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₈ cycloalkyl; (21) C₃-s cycloalkyl-C₁₋₆ alkyl (e.g., -L-R, in which L is C₁₋₆ alkyl and R is C₃₋₈ cycloalkyl); (22) halo; (23) C₁₋₆ haloalkyl (e.g., -L¹-X or -L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., -L¹-OH or -L²-C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., -L¹-NO or -L²-C(NO)(R¹)—R², in which L¹ is C₁₋₆ alkyl; L² is a covalent bond or alkyl; and each of R¹ and R² is, independently, H or C₁₋₆ alkyl, as defined herein); (31)N-protected amino; (32) N-protected amino-C₁₋₆ alkyl; (33) oxo (e.g., ═O); (34) C₁₋₆ thioalkyl (e.g., —S—R, in which R is C₁₋₆ alkyl); (35) thio-C₁₋₆ alkoxy-C₁₋₆ alkyl (e.g., -L-S—R, in which each of L and R is, independently, C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (39) —(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)nCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “aryl-alkyl,” “aryl-alkenyl,” and “aryl-alkynyl” is meant an aryl group, as defined herein, that is or can be coupled (or attached) to the parent molecular group through an alkyl, alkenyl, or alkynyl group, respectively, as defined herein. The aryl-alkyl, aryl-alkenyl, and/or aryl-alkynyl group can be substituted or unsubstituted. For example, the aryl-alkyl, aryl-alkenyl, and/or aryl-alkynyl group can be substituted with one or more substitution groups, as described herein for aryl and/or alkyl. Exemplary unsubstituted aryl-alkyl groups are of from 7 to 16 carbons (C₇₋₁₆ aryl-alkyl), as well as those having an aryl group with 4 to 18 carbons and an alkyl group with 1 to 6 carbons (i.e., C₄₋₁₈ aryl-C₁₋₆ alkyl). Exemplary unsubstituted aryl-alkenyl groups are of from 7 to 16 carbons (C₇₋₁₆ aryl-alkenyl), as well as those having an aryl group with 4 to 18 carbons and an alkenyl group with 2 to 6 carbons (i.e., C₄₋₁₈ aryl-C₂₋₆ alkenyl). Exemplary unsubstituted aryl-alkynyl groups are of from 7 to 16 carbons (C₇₋₁₆ aryl-alkynyl), as well as those having an aryl group with 4 to 18 carbons and an alkynyl group with 2 to 6 carbons (i.e., C₄₋₁₈ aryl-C₂₋₆ alkynyl). In some embodiments, the aryl-alkyl group is -L-R, in which L is an alkyl group or an alkylene group, as defined herein, and R is an aryl group, as defined herein. In some embodiments, the aryl-alkenyl group is -L-R, in which L is an alkenyl group or an alkenylene group, as defined herein, and R is an aryl group, as defined herein. In some embodiments, the aryl-alkynyl group is -L-R, in which L is an alkynyl group or an alkynylene group, as defined herein, and R is an aryl group, as defined herein.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for aryl.

By “arylalkoxy” is meant an aryl-alkyl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C_{6_18} aryloxy group. In other embodiments, R is an aryl group that is optionally substituted with alkyl, alkanoyl, amino, hydroxyl, and the like.

By “aryloxycarbonyl” is meant an aryloxy group, as defined herein, that is attached to the parent molecular group through a carbonyl group. In some embodiments, an unsubstituted aryloxycarbonyl group is a C₅₋₁₉ aryloxycarbonyl group. In other embodiments, the aryloxycarbonyl group is —C(O)O—R, in which R is an aryl group, as defined herein.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “aryloyloxy” is meant an aryloyl group, as defined herein, that is attached to the parent molecular group through an oxy group. In some embodiments, an unsubstituted aryloyloxy group is a C₅₋₁₉ aryloyloxy group. In other embodiments, the aryloyloxy group is —OC(O)—R, in which R is an aryl group, as defined herein.

By “atomic layer deposition” (ALD) is meant a vapor deposition process in which deposition cycles, preferably a plurality of consecutive deposition cycles, are conducted in a process chamber (i.e. a deposition chamber). Typically during each cycle, the precursor is chemisorbed to a deposition surface (i.e. a substrate assembly surface or a previously deposited underlying surface such as material from a previous ALD cycle) forming a monolayer or sub-monolayer that does not readily react with additional precursor (i.e. a self-limiting reaction). Thereafter, if necessary, a reactant (i.e. another precursor or reaction gas) may be introduced into the process chamber for use in converting the chemisorbed precursor to the desired material on the deposition surface. Typically, this reactant is capable of reaction with the already chemisorbed precursor. Further, purging steps may also utilized during each cycle to remove excess precursor from the process chamber and/or remove excess reactant and/or reaction by-products from the process chamber after conversion of the chemisorbed precursor.

By “azido” is meant an -N₃ group.

By “azidoalkyl” is meant an azido group attached to the parent molecular group through an alkyl group, as defined herein. In some embodiments, the azidoalkyl group is -L-N₃, in which L is an alkyl group, as defined herein.

By “azo” is meant an —N═N— group.

By “bidentate ligand” is meant a ligand having two atoms that coordinate to a central atom in a complex, i.e. an alkyl diamine.

By “carbamoyl” is meant an amino group attached to the parent molecular group through a carbonyl group, as defined herein. In some embodiments, the carbamoyl is —C(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbamoyloxy” is meant a carbamoyl group, as defined herein, attached to the parent molecular group through n oxy group, as defined herein. In some embodiments, the carbamoyl is —OC(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbonimidoyl” is meant a —C(NR)— group. In some embodiments, R is selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof.

By “carbonyl” is meant a —C(O)— group, which can also be represented as >C═O.

By “carboxyl” is meant a —CO₂H group or an anion thereof.

By “catalyst” is meant a compound, usually present in small amounts relative to reactants, capable of catalyzing a synthetic reaction, as would be readily understood by a person of ordinary skill in the art. In some embodiments, catalysts may include transition metal coordination complex.

By “cyanato” is meant a —OCN group.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant a —O-L-R group, in which L is an alkyl group or an alkylene group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be substituted or unsubstituted. For example, the cycloalkyl group can be substituted with one or more groups including those described herein for alkyl. Further, cycloalkyl may include one or more double bonds and/or triple bonds.

By “cycloheteroaliphatic” is meant a heteroaliphatic group, as defined herein, that is cyclic.

By “deposition” or “vapor deposition” is meant a process in which a metal layer is formed on one or more surfaces of a substrate from vaporized precursor composition(s) including one or more metal containing compounds. The metal-containing compounds are vaporized and directed to and/or contacted with one or more surfaces of a substrate (i.e., semiconductor substrate or semiconductor assembly) placed in a deposition chamber. Typically the substrate is heated. These metal containing compounds form a non-volatile, thin, uniform metal-containing layer on the surface(s) of the substrate. One operation of the method is one cycle, and the process can be repeated for as many cycles necessary to obtain the desired metal thickness.

By “disilanyl” is meant a group containing an Si—Si bond. In some embodiments, the disilanyl group is a —SiR^{S1}R^{S2}—SiR^{S3}R^{S4}R^{S5} or —SiR^{S1}R^{S2}—SiR^{S3}R^{S4}— group, in which each of R^{S1}, R^{S2}, R^{S3}, R^{S4}, and R^{S5} is, independently, H, optionally substituted aliphatic, optionally substituted heteroaliphatic, optionally substituted aromatic, optionally substituted heteroaromatic, or optionally substituted amino.

By “disulfide” is meant —SSR, where R is selected from hydrogen, aliphatic, heteroaliphatic, haloaliphatic, haloheteroaliphatic, aromatic, as defined herein, or any combination thereof.

By “electron-donating group” is meant a functional group capable of donating at least a portion of its electron density into the ring to which it is directly attached, such as by resonance.

By “electron-withdrawing group” is meant a functional group capable of accepting electron density from the ring to which it is directly attached, such as by inductive electron withdrawal.

By “halo” is meant F, Cl, Br, or I.

By “chalcogen” is meant, O, S, Se or Te.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the haloalkyl group is -L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaliphatic group is unsubstituted or substituted, e.g., by a functional group described herein. For example, the heteroaliphatic group can be substituted with one or more substitution groups, as described herein for alkyl.

By “heteroaliphatic-carbonyl” is meant a heteroaliphatic group that is or can be coupled to a compound disclosed herein, wherein the heteroaliphatic group is or becomes coupled through a carbonyl group (—C(O)—). In some embodiments, the heteroaliphatic-carbonyl group is —C(O)—R, in which R is an optionally substituted heteroaliphatic group, as defined herein.

By “heteroaliphatic-carbonyloxy” is meant a heteroaliphatic group that is or can be coupled to a compound disclosed herein, wherein the heteroaliphatic group is or becomes coupled through a carbonyloxy group (—OC(O)—). In some embodiments, the heteroaliphatic-carbonyloxy group is —OC(O)—R, in which R is an optionally substituted heteroaliphatic group, as defined herein.

By “heteroaliphatic-oxy” is meant a heteroaliphatic group that is or can be coupled to a compound disclosed herein, wherein the heteroaliphatic group is or becomes coupled through an oxy group (—C(O)—). In some embodiments, the heteroaliphatic-oxy group is —O—R, in which R is an optionally substituted heteroaliphatic group, as defined herein.

By “heteroaliphatic-oxycarbonyl” is meant a heteroaliphatic group that is or can be coupled to a compound disclosed herein, wherein the heteroaliphatic group is or becomes coupled through an oxycarbonyl group (—C(O)O—). In some embodiments, the heteroaliphatic-oxycarbonyl group is —C(O)O—R, in which R is an optionally substituted heteroaliphatic group, as defined herein.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkylene,” “heteroalkenylene,” and “heteroalkynylene” is meant a multivalent (e.g., bivalent) form of a heteroalkyl, heteroalkenyl, or heteroalkynyl group, respectively, as described herein.

By “heteroaromatic” is meant an aromatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaromatic group is unsubstituted or substituted, e.g., by a functional group described herein. For example, the heteroaromatic group can be substituted with one or more substitution groups, as described herein for alkyl and/or aryl.

By “heteroaromatic-carbonyl” is meant a heteroaromatic group that is or can be coupled to a compound disclosed herein, wherein the heteroaromatic group is or becomes coupled through a carbonyl group (—C(O)—). In some embodiments, the heteroaromatic-carbonyl group is —C(O)—R, in which R is an optionally substituted heteroaromatic group, as defined herein.

By “heteroaromatic-carbonyloxy” is meant a heteroaromatic group that is or can be coupled to a compound disclosed herein, wherein the heteroaromatic group is or becomes coupled through a carbonyloxy group (—OC(O)—). In some embodiments, the heteroaromatic-carbonyloxy group is —OC(O)—R, in which R is an optionally substituted heteroaromatic group, as defined herein.

By “heteroaromatic-oxy” is meant a heteroaromatic group that is or can be coupled to a compound disclosed herein, wherein the heteroaromatic group is or becomes coupled through an oxy group (—O—). In some embodiments, the heteroaromatic-oxy group is —O—R, in which R is an optionally substituted heteroaromatic group, as defined herein.

By “heteroaromatic-oxycarbonyl” is meant a heteroaromatic group that is or can be coupled to a compound disclosed herein, wherein the heteroaromatic group is or becomes coupled through an oxycarbonyl group (—C(O)O—). In some embodiments, the heteroaromatic-carbonyl group is —C(O)O—R, in which R is an optionally substituted heteroaromatic group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An exemplary heteroaryl includes a subset of heterocyclyl groups, as defined herein, which are aromatic, i.e., they contain 4n+2 pi electrons within the mono- or multicyclic ring system.

By “heteroarylene” is meant a multivalent (e.g., bivalent) form of a heteroaryl group, as described herein.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydrazino” is meant —NR¹—NR²R³, where each of R¹, R², and R³ is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where a combination of R¹ and R² or a combination of R² and R³, taken together with the nitrogen atom to which each are attached, can form a heterocyclyl group, as defined herein. In some embodiments, each of R¹, R², or R³ is, independently, H, optionally substituted alkyl, optionally substituted aryl, optionally substituted alkyl-aryl, or optionally substituted aryl-alkyl. In particular embodiments, R² and R³ can be taken together, with the nitrogen atom to which each is attached, to form an optionally substituted heterocyclyl.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(R¹)—R², in which L is a covalent bond or an alkyl group, as defined herein, and each of R¹ and R² is, independently, H or alkyl, as defined herein.

By “imidoyl” is meant a moiety including a carbonimidoyl group. In some embodiments, the imidoyl group is C(NR¹)R², in which each of R¹ and R² is, independently, selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof. In other embodiments, the imidoyl group is —C(NR¹)H, —C(NR¹)R^{Ak}, or —C(NR^{N1})R^{Ar}, in which R¹ is hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, or optionally substituted silyloxy; R^{Ak} is an optionally substituted alkyl or an optionally substituted aliphatic; and RA is an optionally substituted aryl or an optionally substituted aromatic.

By “imino” is meant a —NR— group. In some embodiments, R is selected from hydrogen, optionally substituted aliphatic, optionally substituted heteroaliphatic, optionally substituted aromatic, or optionally substituted heteroaromatic. In particular embodiments, R is H, optionally substituted alkyl, optionally substituted alkoxy, optionally substituted aryl, optionally substituted aryloxy, optionally substituted alkyl-aryl, or optionally substituted aryl-alkyl.

By “isocyanato” is meant a —NCO group.

By “isocyano” is meant a —NC group.

By “ketone” is meant —C(O)R or a compound including such a group, where R is selected from aliphatic, heteroaliphatic, aromatic, as defined herein, or any combination thereof. An example of a ketone can include R¹C(O)R, in which each of R and R¹ is, independently, selected from aliphatic, haloaliphatic, haloheteroaliphatic, heteroaliphatic, aromatic, aliphatic-aromatic, heteroaliphatic-aromatic, as defined herein, or any combination thereof.

“Molybdenum metal” or “metallic molybdenum” as used herein, refers to material that consists essentially of molybdenum (Mo) in zero oxidation state. Other elements (e.g., C, N, or O) can be present in molybdenum metal in small quantities (e.g., with a total content of less than about 15 atomic %, or less than about 10%, where hydrogen is not included in the calculation). “High purity molybdenum metal” as used herein refers to molybdenum metal that includes less than about 5% of other elements, such as less than about 1% of other elements, where hydrogen is not included in the calculation. In some embodiments, molybdenum metal deposited by provided methods includes at least a portion that is at least about 90% such as at least about 95%, or at least about 99% pure molybdenum, where % refer to weight percent.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “plasma generated remotely” is meant a plasma created at a different location from, or outside of, a deposition chamber.

By “salt” is meant an ionic form of a compound or structure (e.g., any formulas, compounds, or compositions described herein), which includes a cation or anion compound to form an electrically neutral compound or structure. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amino cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “singly deuterated ammonia” is meant NH₂D.

By “doubly deuterated ammonia” is meant NHD₂.

By “triply deuterated ammonia” is meant ND₃.

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like. The term “semiconductor substrate” or “substrate” as used herein refers to a substrate at any stage of semiconductor device fabrication containing a semiconductor material anywhere within its structure. It is understood that the semiconductor material in the semiconductor substrate does not need to be exposed. Semiconductor wafers having a plurality of layers of other materials (e.g., dielectrics) covering the semiconductor material, are examples of semiconductor substrates. The following detailed description assumes the disclosed implementations are implemented on a semiconductor wafer, such as on a 200 mm, 300 mm, or 450 mm semiconductor wafer. However, the disclosed implementations are not so limited. The work piece may be of various shapes, sizes, and materials. In addition to semiconductor wafers, other work pieces that may take advantage of the disclosed implementations include various articles such as printed circuit boards and the like.

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl

By “substituted” is meant having one or more substituent moieties whose presence does not interfere with the desired function or reactivity. Examples of substituents alkyl, alkenyl, alkynyl, cycloalkyl (non-aromatic ring), Si(alkyl)₃, Si(alkoxy)₃, alkoxy, amino, alkylamino, alkenylamino, amide, amidine, guanidine, hydroxyl, thioether, alkylcarbonyl, alkylcaronyloxy, alkoxycarbonyloxy, carbonate, alkoxycarbonyl, aminocarbonyl, alkylthiocarbonyl, phosphate, phosphate ester, phosphonato, cyano, halo, acylamino, imino, sulfhydryl, alkylthio, thiocarboxylate, dithiocarboxylate, sulfate, sulfato, sulfonate, sulfamoyl, sulfonamide, nitro, nitrile, azido, heterocyclyl, ether, ester, silicon-containing moieties, thioester or a combination thereof. The substituents may themselves be substituted. For instance, an amino substituent may itself be mono or independently disubstituted by further substituents defined above, such as alkyl, alkenyl, alkynyl, and cycloalkyl (non-aromatic ring).

By “sulfinyl” is meant an —S(O)— group.

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, haloheteroaliphatic, aromatic, as defined herein, or any combination thereof.

By “temporally separate pulses” is meant a delivery of an amount of a gas flow in an amount of time.

By “thioalkyl” is meant an alkyl group, as defined herein, attached to the parent molecular group through a sulfur atom. Exemplary unsubstituted thioalkyl groups include C₁₋₆ thioalkyl. In some embodiments, the thioalkyl group is —S—R, in which R is an alkyl group, as defined herein.

By “thiol” is meant an —SH group.

By “unsubstituted” is meant any open valence of an atom being occupied by hydrogen. Also, if an occupant of an open valence position on an atom is not specified, then it is hydrogen.

By “vapor phase metal precursor” is meant a metal precursor in a gaseous state at a temperature where it can exist in both liquid and solid states.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

Other features and advantages of the invention will be apparent from the following description and the claims. According to various embodiments, one or more of the following advantages may be realized by the methods described herein.

In semiconductor device fabrication, deposition and etching techniques are used for forming patterns of materials, such as for forming metal lines embedded in dielectric layers. Some patterning schemes utilize conformal deposition of materials, where the deposited layer may follow the contour of protrusions and/or recessed features on the surface of the substrate. Atomic layer deposition (ALD) is a method of forming conformal films on a substrate, that uses adsorption of one or more reactants (precursors) to the surface of the substrate, and on subsequent chemical transformation of the adsorbed layer to the desired material. Because ALD uses sequential reactions that occur on the surface of the substrate, that are separated in time, and that may be limited by the amount of the adsorbed reactant, this method can provide thin conformal layers having excellent step coverage.

ALD may employ plasma to promote the reactions of the deposition precursors resulting in the formation of the desired films. The method that makes use of plasma is known as plasma enhanced ALD (PEALD). The method that does not employ plasma is referred to as thermal ALD.

ALD may be used for deposition of silicon-containing films, such as silicon oxide, silicon nitride, and silicon carbide, the method is also suitable for deposition of other materials such as metals.

In semiconductor fabrication, features such as lines and vias may be filled with conductive materials such as tungsten (W), copper (Cu), and cobalt (Co). As semiconductor devices scale down to 10 nm node and lower, line and via contact resistance increase rapidly in metal interconnects. This is due to the reduction in current-carrying cross-section, increase in electron scattering, and the increasing challenges of filling narrow features with current Cu or W process schemes in narrow features.

Provided are reduced-temperature plasma enhanced atomic layer deposition (PEALD) processes including application of a thin metal layer by contacting a substrate surface at temperatures of 300° C. or lower with a metal precursor and a plasma of a hydrogen-containing gas source generated remotely. In some embodiments, the metal is molybdenum.

Atomic layer deposition of molybdenum may be achieved by a thermal reaction with H₂ gas to remove molybdenum precursor ligands at temperatures of 400° C. or higher. However, such high temperature conditions may be less well suited to back end of line applications, due to the sensitivity of previously deposited layers.

The reduced temperature conditions of the method of molybdenum deposition in accordance with certain disclosed embodiments are suitable for back end of the line applications. Moreover, the use of a remote plasma under some circumstances in accordance with certain disclosed embodiments avoids the damaging of low K materials which can occur when a direct plasma source is employed.

Copper deposition may be accomplished by electroplating. However, electroplating has drawbacks due to the requirement for a surface-conducting layer to provide an electric field used to deposit the copper. Specifically, in a device structure with 50 nm openings to fill, up to 30 nm may be taken up by a conducting liner necessary to distribute the electric field, severely limiting the fill width of low resistivity copper metal. Copper scaling is limited by a steep increase in resistivity as line width decreases below 10-20 nm. Morphology is another factor which must be taken into consideration for a copper deposition process. Rough, discontinuous and island-like morphology may result in deposition of copper films by atomic layer deposition as the film approaches the limit of several atomic monolayers. A thin copper film deposited in accordance with certain disclosed embodiments produces smoother morphology or lower resistivity or both smoother morphology and lower resistivity.

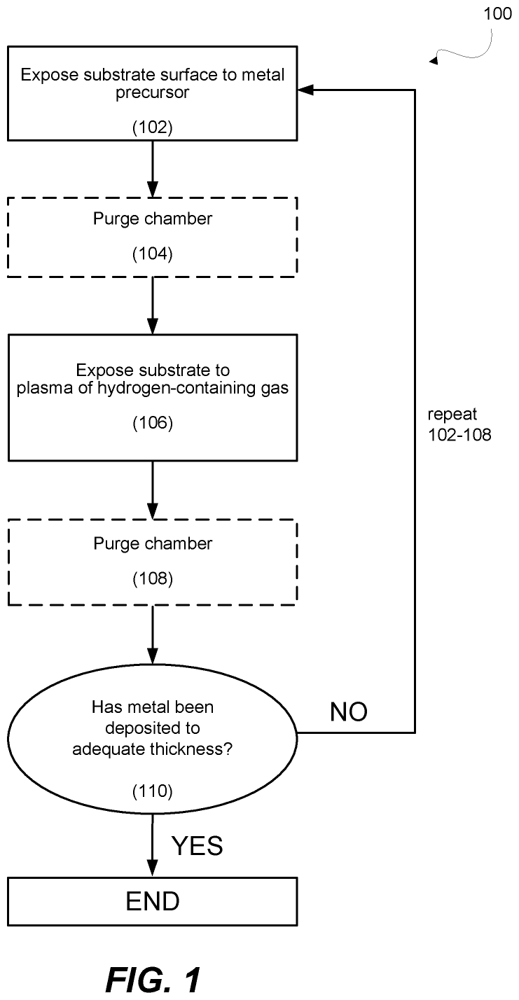

FIG. 1 schematically shows a non-limiting process for ultra-thin film metal deposition. Examples of applications include middle-of-line (MOL) or back end of line (BEOL) interconnects. In one example, the methods may be used for source/drain contact fill. Process 100 begins with providing a substrate including a surface and/or a feature in which a metal is to be deposited. The substrate may be provided to a semiconductor processing tool.

The substrate may be a silicon wafer, e.g., a 200-mm wafer, a 300-mm wafer, or a 450-mm wafer, including wafers having one or more layers of material, such as dielectric, conducting, or semi-conducting material deposited thereon. In various embodiments, the substrate is patterned. A patterned substrate may have “features” such as pillars, poles, trenches, via or contact holes, which may be characterized by one or more of narrow and/or re-entrant openings, constrictions within the feature, and high aspect ratios. The feature(s) may be formed in one or more of the above-described layers. One example of a feature is a pillar or pole in a semiconductor substrate or a layer on the substrate. Another example is a trench in a substrate or layer.

In some embodiments, the feature(s) such as a pillar may have an aspect ratio of at least about 1:1, at least about 2:1, at least about 4:1, at least about 6:1, at least about 10:1, or higher. The feature(s) may also have a dimension near the opening, e.g., an opening diameter or line width of between about 10 nm to 500 nm, for example between about 25 nm and about 300 nm. Disclosed methods may be performed on substrates with feature(s) having an opening less than about 150 nm. A via, trench or other recessed feature may be referred to as an unfilled feature or a feature. According to various embodiments, the feature profile may narrow gradually and/or include an overhang at the feature opening. A re-entrant profile is one that narrows from the bottom, closed end, or interior of the feature to the feature opening. A re-entrant profile may be generated by asymmetric etching kinetics during patterning and/or the overhang due to non-conformal film step coverage in the previous film deposition, such as deposition of a diffusion barrier. In various examples, the feature may have a width smaller in the opening at the top of the feature than the width of the bottom of the feature.

The feature may be a trench or via that is formed in a dielectric layer. Examples of dielectric materials include oxides, such as silicon oxide (SiO₂) and aluminum oxide (Al₂O₃); nitrides, such as silicon nitride (SiN); carbides, such as nitrogen-doped silicon carbide (NDC) and oxygen-doped silicon carbide (ODC); and low K dielectrics, such as carbon-doped SiO₂. The metal may be deposited in the feature to make electrical contact to an underlying layer. Examples of underlying layers include metals, metal silicides, and semiconductors. Examples of metals include Co, Ru, copper (Cu), W, Mo, nickel (Ni), iridium (Ir), rhodium (Rh), tantalum (Ta), and titanium (Ti). Examples of metal silicides include TiSiₓ, nickel silicide (NiSiₓ), molybdenum silicide (MoSiₓ), cobalt silicide (CoSiₓ), platinum silicide (PtSiₓ), ruthenium silicide (RuSiₓ), and nickel platinum silicide (NiPt_{y}Siₓ). Examples of semiconductors include silicon (Si), silicon germanium (SiGe), and gallium arsenide (GaAs) with or without semiconductor dopants such as carbon (C), arsenic (As), boron (B), phosphorus (P), tin (Sn), and antimony (Sb).

The feature generally has sidewall surfaces and a bottom surface. In some embodiments, the sidewall surfaces may be the same material as the bottom surface. For example, in some embodiments, the sidewall surfaces and the bottom surface are titanium nitride (TiN). In some embodiments, the sidewall surfaces may be a different material than the material of the bottom surface. For example, the bottom surface may be a metal silicide and the sidewall surface may be a silicon oxide, such as SiO₂.

The substrate that is provided to the chamber may have a liner layer deposited in features on the substrate. An exposed surface of the substrate may include liner material. Prior to any metal deposition, a liner layer may line the unfilled feature and form the sidewall surfaces and/or bottom surface. In some embodiments, a liner layer lines the whole feature and forms the sidewall surfaces and bottom surface. In some other embodiments, the liner layer lines only a portion of the feature. For example, a TiN layer may line the sidewalls with the bottom surface unlined. Examples of materials for liner layers include metal nitrides (e.g., a TiN or tantalum nitride (TaN) barrier layer) and metals (e.g., a Ti adhesion layer).

Atomic Layer Deposition (ALD) is a technique that deposits thin layers of material using sequential self-limiting reactions. ALD processes use surface-mediated deposition reactions to deposit films on a layer-by-layer basis in cycles. As an example, an ALD cycle may include the following operations: (i) delivery/adsorption of a precursor, (ii) purging of precursor from the chamber, (iii) delivery of a second reactant and optionally ignite plasma, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc. In ALD deposition of metal films, this reaction involves reacting oxygen plasma with carbon and nitrogen to form a gaseous species; oxidizing metal to metal oxide; eliminating trace carbon, nitrogen, and hydrogen impurities; and increasing bonding and densification of the film.

Unlike a chemical vapor deposition (CVD) technique, ALD processes use surface-mediated deposition reactions to deposit films on a layer-by-layer basis. In one example of an ALD process, a substrate surface that includes a population of surface-active sites is exposed to a gas phase distribution of a first precursor, such as a metal-containing precursor, in a dose provided to a chamber housing a substrate. Molecules of this first precursor are adsorbed onto the substrate surface. It should be understood that when a compound is adsorbed onto the substrate surface as described herein, the adsorbed layer may include the compound as well as derivatives of the compound. For example, an adsorbed layer of a metal-containing precursor may include the metal-containing precursor as well as derivatives of the metal-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen-containing gas, is introduced to the chamber so that some of these molecules react with the first precursor adsorbed on the surface. In some processes, the second precursor reacts immediately with the adsorbed first precursor. In other embodiments, the second reactant reacts only after a source of activation is applied temporally. The chamber may then be evacuated again to remove unbound second reactant molecules. As described above, in some embodiments the chamber may not be completely evacuated. Additional ALD cycles may be used to build film thickness.

In some implementations, the ALD methods include plasma activation. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” and in U.S. patent application Ser. No. 13/084,305, filed Apr. 11, 2011, and titled “SILICON NITRIDE FILMS AND METHODS,” which are herein incorporated by reference in their entireties.

Once the substrate is provided, a metal is deposited in the feature and/or on the substrate surface in process 100. Metals that may be deposited include vanadium, niobium, tantalum, chromium, cobalt, tungsten, iron, ruthenium, nickel, zinc, copper or molybdenum. The metals may include less than about 5% of other elements, such as less than about 1% of other elements, where hydrogen is not included in the calculation. In some embodiments, the metal deposited by provided methods includes at least a portion that is at least about 90% such as at least about 95%, or at least about 99% pure metal, where % refer to weight percent.

The metal may be deposited by a plasma enhanced atomic layer deposition (PEALD) method. PEALD is a surface-mediated deposition technique in which doses of a precursor and a reactant (a reducing gas in plasma form) are sequentially introduced into a deposition chamber. In some embodiments, the gas is pure hydrogen, hydrogen mixed with inert argon or helium. In some embodiments, small amounts of oxygen may also be added. Total flow rate will depend upon chamber geometry and size. The amount of hydrogen may range from about 100% when pure hydrogen is utilized to about 5% hydrogen when mixed with an inert gas. For PEALD, the temperature of the substrate and the pressure of a chamber may be controlled. In some embodiments, the substrate may be heated to a temperature of about 300° C. or lower, e.g., about 300° C. to about 50° C. In some embodiments, the chamber may be pressurized to less than about 10 Torr. In some embodiments, the chamber pressure may be in the range of from about 0.1 to about 9.9 Torr. In some embodiments, the duration of exposure is from about 5 or 10 seconds to about 2 minutes.

In an operation 102, a substrate surface is exposed to a metal precursor. In some embodiments, the metal precursors may be molybdenum precursors, copper precursors, tungsten precursors, cobalt precursors or ruthenium precursors among others. Exemplary metal precursors are discussed in the following paragraphs.

### Copper Precursors

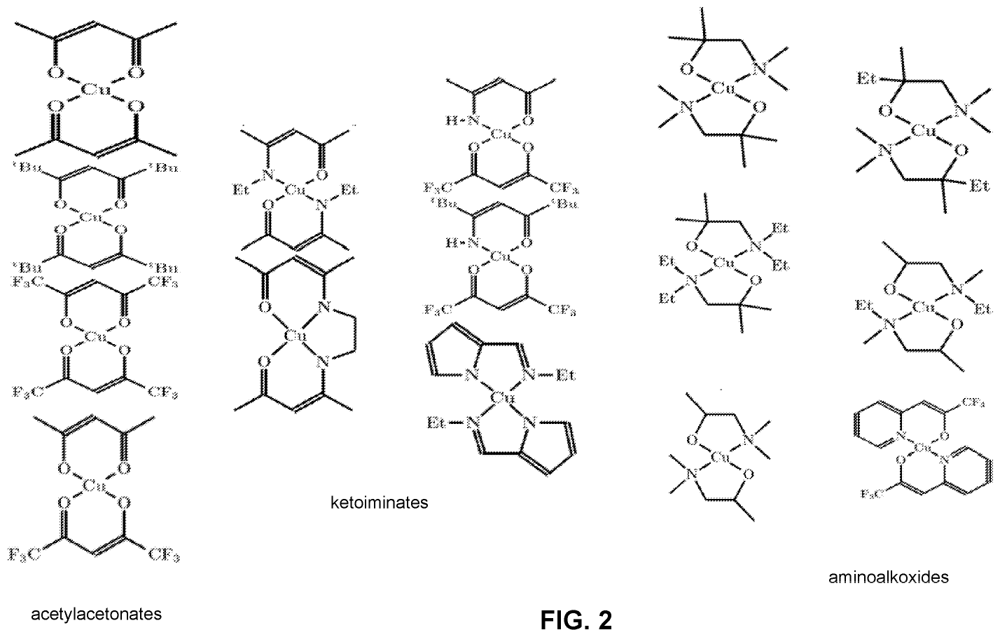

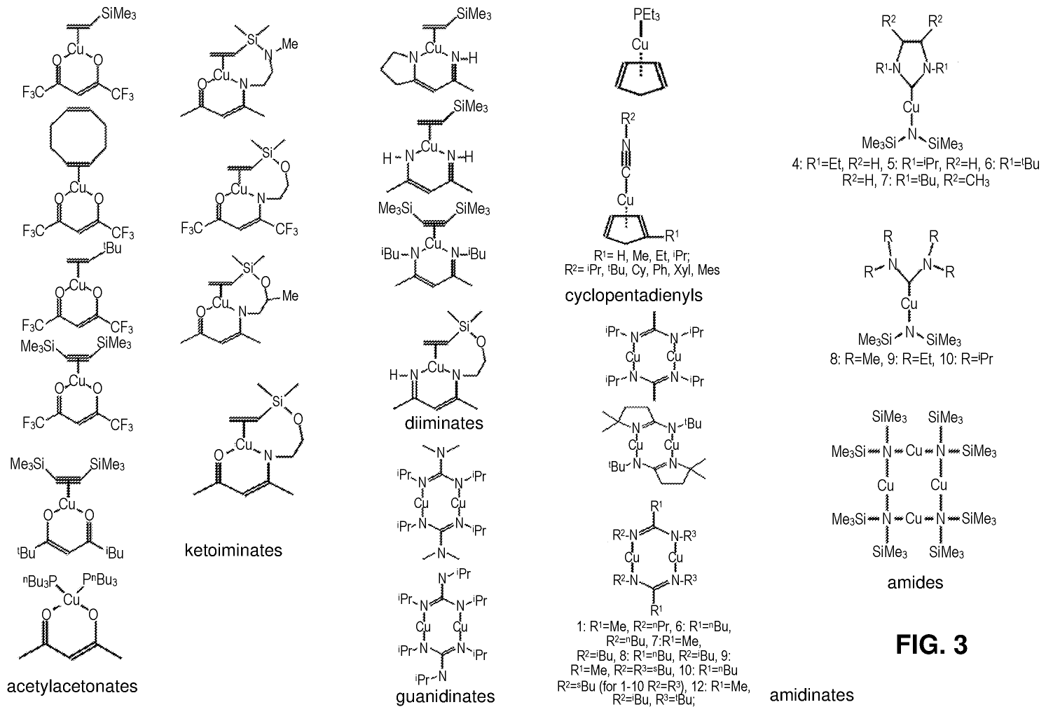

Copper metal can be deposited using a variety of copper precursors, where copper may be in +1 or +2 oxidation states. The precursors may be cuprous (copper (I)) compounds such as acetylacetonates, ketoiminates, diiminates, cyclopentadienyl compounds, amidinates, guanidinates or amides; or cupric (copper (II)) compounds such as acetylacetonates, ketominates or aminoalkoxides as illustrated in FIG. 2 and FIG. 3. In some embodiments the precursors are coordination complexes, where copper coordinates to a multiple bond such as a double or triple bond; or coordinates to the oxygen of a carbonyl group for example.

Examples of copper precursors include Cu(acac)₂ where acac=acetylacetonato; Cu(thd)₂ where thd=tetrahydrodionato); hexafluoroacetylacteonate-copper-trimethylsilane; cyclopentadienyl (Cp) compounds such as CpCu(CNMe), CpCu(CNCMe₃), CpCuCO, CPCuPR₃ (where R=Me, Et or Ph) and CpCu(CSiMe₃)₂; alkyl or aryl compounds such as MeCu(PPh₃)₃, CuMe, CuCCH(ethynylcopper), CuCMe₃ (methylacetylide copper), (H₂C═CMeCC)Cu(3-methyl-3-buten-1ynylcopper), CuCCPh, C₆H₅Cu (phenyl copper), (Me)₃CCCCu (3,3-dimethyl-1-butynyl) copper, Me₃SiCCCH₂Cu; and other compounds such as CuCN, [Cu(OAc]ₙ (where OAc=acetate), Cu₂Cl₂(butadiene), C₇H₇CuO(2-methoxyphenylcopper), (MeCN)₄CuX (where X is a halide, an alkyl, an amine or a phenyl group), Me₃SiOCu(PMe₃)₃, Cu(C₄H₄S) and Cu-carbene compounds such as those derived from imidazolium.

### Molybdenum-Containing Precursors

Generally, molybdenum-containing precursors can include molybdenum in a wide range of oxidation states ranging from 0 to +6. In some embodiments, molybdenum compounds have molybdenum in low oxidation states of +3, +4 and +5. Provided methods are particularly useful for depositing molybdenum containing materials from halogen-containing molybdenum-containing compounds, because silicon-containing reactants can assist in halogen scavenging, but halogen-free molybdenum-containing precursors can be used as well. Suitable molybdenum containing precursors include molybdenum halides and oxyhalides, such as fluorides, chlorides, bromides, oxyfluorides, oxychlorides, and oxybromides where molybdenum may be in any of the oxidation states from +2 to +6.

Molybdenum chloride precursors are given by the formula MoCₓ, where x is 2, 3, 4, 5, or 6, and include molybdenum dichloride (MoCl₂), molybdenum trichloride (MoCl₃), molybdenum tetrachloride (MoCl₄), molybdenum pentachloride (MoCl₅), and molybdenum hexachloride (MoCl₆). In some embodiments, MoCl₅ or MoCl₆ are used. While the description chiefly refers to MoClₓ precursors, in other embodiments, other molybdenum halide precursors may be used. Molybdenum halide precursors are given by the formula MoX_{z}, where X is a halogen (fluorine (F), chlorine (Cl), bromine (Br), or iodine (I)) and z is 2, 3, 4, 5, or 6. Examples of MoX_{z} precursors include molybdenum fluoride (MoF₆). In some embodiments, a non-fluorine-containing MoX_{z} precursor is used to prevent fluorine etch or incorporation. In some embodiments, a non-bromine-containing and/or a non-iodine-containing MoX_{z} precursor is used to prevent etch or bromine or iodine incorporation.

Molybdenum oxyhalide precursors are given by the formula MoO_{y}X_{z}, where X is a halogen (fluorine (F), chlorine (Cl), bromine (Br), or iodine (I)) and y and z are numbers greater than 0 such that MoO_{y}X_{z} forms a stable compound. Examples of molybdenum oxyhalides include molybdenum dichloride dioxide (MoO₂Cl₂), molybdenum tetrachloride oxide (MoOCl₄), molybdenum tetrafluoride oxide (MoOF₄), molybdenum dibromide dioxide (MoO₂Br₂), and the molybdenum iodides MoO₂I, and Mo₄O₁₁I.

In some embodiments discussed herein, the precursors having molecular weights of less than about 450 g/mol, such as less than about 400 g/mol.

In some embodiments the molybdenum containing precursor has a formula MoXₙYₘ, wherein X is a chalcogen (e.g., oxygen or sulfur), Y is a halogen (e.g., fluorine, chlorine, bromine, or iodine), n is 0, 1, or 2 and m is 2, 3, 4, 5, or 6. Examples of halogen-containing molybdenum-containing precursors include without limitation MoC₅, Mo₂Cl₁₀, MoO₂Cl₂, and MoOCl₄. Another example of a halogen-containing molybdenum-containing precursor is MoF₆.

In some embodiments molybdenum-containing precursor includes carbonyl ligands. An example of a carbonyl-containing precursor is Mo(CO)₆.

In some embodiments, the processes include deposition of a thin, protective Mo layer using a molybdenum chloride (MoClₓ) precursor. This may be followed by Mo deposition to fill the feature using a molybdenum oxyhalide (MoO_{y}X_{z}) precursor. The protective Mo layer enables Mo fill using an MoO_{y}X_{z} precursor without oxidation of an underlying surface. This can be useful for oxygen-sensitive surfaces such as silicon (Si), silicon germanium (SiGe), titanium (Ti), titanium nitride (TiN) and titanium silicide (TiSi₂). Also provided are clean and etch processes in which a MoClₓ precursor is used to remove oxide(s) from underlying surfaces prior to deposition. Subsequent deposition using the MoClₓ precursor may yield a liner layer and/or fill a feature. The protective Mo layer protects the bottom surface of the feature. In some embodiments, it is deposited selectively on the bottom surface with little or no deposition on the feature sidewalls. In some embodiments, it is deposited non-selectively on the bottom and sidewall surfaces.

### Halide-Containing Heteroleptic Molybdenum Compounds

In one aspect, halide-containing heteroleptic molybdenum compounds are used as precursors for deposition of molybdenum-containing films, such as for deposition of molybdenum metal. In one embodiment, the precursor is a compound that includes molybdenum, at least one halide forming a bond with molybdenum, and at least one organic ligand having any of the N, O, and S elements, where an atom of any of these elements forms a bond with molybdenum. Examples of suitable organic ligands that provide nitrogen or oxygen bonding include amidinates, amidates, iminopyrrolidinates, diazadienes, beta-imino amides, alpha-imino alkoxides, beta-amino alkoxides, beta-diketiminates, beta-ketoiminates, beta-diketonates, amines, and pyrazolates. Examples of suitable organic ligands that provide sulfur bonding include thioethers, thiolates, dithiolenes, dithiolates, and α-imino thiolenes. These ligands may be substituted or unsubstituted. In some embodiments, these ligands include one or more substituents independently selected from the group consisting of H, alkyl, fluoroalkyl, alkylsilyl, alkylamino, and alkoxy substituents. The organic ligands can be neutral or anionic (e.g., monoanionic or dianionic), and molybdenum can be in a variety of oxidation states, such as +1, +2, +3, +4, +5, and +6.

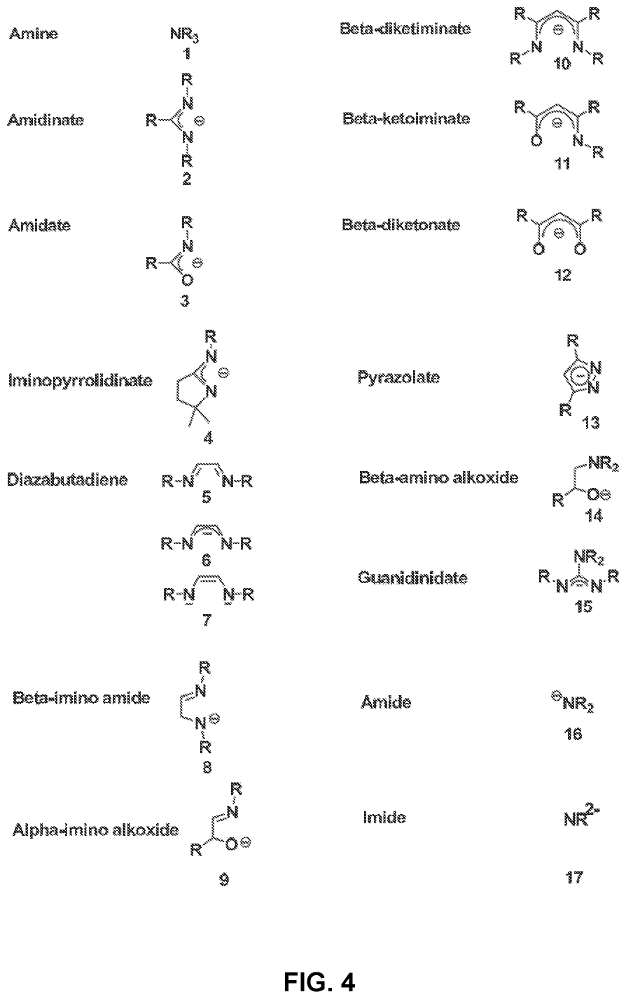

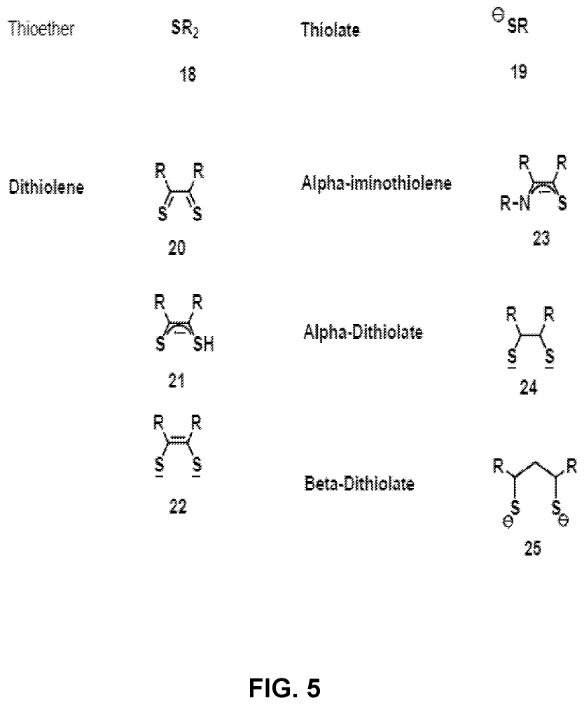

Structures of exemplary suitable N and/or O containing organic ligands 1-17 are shown in FIG. 4, and structures of exemplary suitable S-containing organic ligands 18-25 are shown in FIG. 5, where each R is independently selected from H, alkyl, fluoroalkyl, alkylsilyl, alkylamino, and alkoxy. In some embodiments, each R is independently selected from H, alkyl, and fluoroalkyl. In some embodiments each R is independently selected from H, methyl, ethyl, n-propyl, isopropyl, isobutyl, n-butyl, sec-butyl, t-butyl, pentyl, hexyl, cyclopropyl, cyclobutyl, cyclopentyl, cyclohexyl, cyclopropylmethyl, cyclopropylethyl, cyclopropylpropyl, cyclobutylmethyl, and cyclobutylethyl. In some embodiments each R is an independently selected alkyl. In some embodiments ligands with branched alkyl substituents, such as isopropyl, and isobutyl are preferred, because such ligands provide more volatile molybdenum precursors.

In some embodiments, at least one organic ligand in the precursor is an amine. Suitable amines include unidentate amines (e.g., monoalkylamines, dialkylamines), bidentate amines (e.g., unsubstituted or N-alkyl substituted ethylenediamines), and amines of higher denticities (e.g., substituted or unsubstituted diethylenetriamine). An example of a monodentate amine is amine 1, shown in FIG. 4, where at least one R is an alkyl or fluoroalkyl, and each R is independently selected from the group consisting of H, alkyl, and fluoroalkyl. In some embodiments at least one R is an alkyl, and each R is independently selected from H, and an alkyl. In some embodiments, the at least one organic ligand is an amide, such as a monoanionic amide 16, wherein at least one R is an alkyl or fluoroalkyl, and each R is independently selected from H, alkyl, and a fluoroalkyl. In some embodiments, the at least one organic ligand is an imide, such as a dianionic imide 17, wherein R is an alkyl or fluoroalkyl. While in general imide-containing precursors can be used for deposition of a variety of molybdenum-containing films (including molybdenum metal), in some embodiments they are more preferred for deposition of molybdenum nitride and molybdenum carbonitride, as they form strong molybdenum-nitrogen bonds, and can serve as sources of nitrogen for the resulting film. In some embodiments, at least one organic ligand in the precursor is an amidinate. An example of an amidinate is an amidinate 2 shown in FIG. 4, where each R is independently selected from H, alkyl, and fluoroalkyl. Amidinate 2 is a monoanionic ligand that can form two molybdenum-nitrogen bonds, serving as a bidentate ligand.

In some embodiments, at least one organic ligand in the precursor is an amidate. An example of an amidate is an amidate 3 shown in FIG. 4, where each R is independently selected from H, alkyl, and fluoroalkyl. Amidate 3 is a monoanionic ligand that can form one molybdenum-nitrogen, and one molybdenum-oxygen bond, serving as a bidentate ligand.

In some embodiments, at least one organic ligand in the precursor is a diazadiene. Examples of diazadienes are 1,4-diazabuta-1,3-dines (DAD) 5, 6, and 7, where each R is independently selected from H, alkyl, and fluoroalkyl. An interesting property of this ligand is that it can exist in neutral form 5, monoanionic radical form 6, and dianionic form 7. Due to redox activity of monoanionic (radical) form 6, it can be relatively easily removed during deposition making complexes of DAD 6 particularly useful for deposition of molybdenum metal and high purity molybdenum metal. DAD ligands 5, 6, and 7 can serve as bidentate ligands, each forming two molybdenum-nitrogen bonds. In some embodiments the molybdenum precursor includes DAD ligand 5, 6, or 7 as an organic ligand, where each R is independently selected from methyl, ethyl, propyl, isopropyl, n-butyl, isobutyl, sec-butyl and t-butyl.

In some embodiments, the at least one organic precursor is an iminopyrrolidinate (such as an iminopyrrolidinate 4, where each R is independently selected from H, alkyl, and fluoroalkyl), a beta-imino amide (such as beta-imino amide 8, where each R is independently selected from H, alkyl, and fluoroalkyl), an alpha-imino alkoxide (such as an alpha-imino alkoxide 9, where each R is independently selected from H, alkyl, and fluoroalkyl), a beta-diketiminate (such as an beta-diketiminate 10, where each R is independently selected from H, alkyl, and fluoroalkyl), a beta-ketoiminate (such as beta-ketoiminate 11, where each R is independently selected from H, alkyl, and fluoroalkyl), a beta-diketonate 12 (such as beta-diketonate 12, where each R is independently selected from H, alkyl, and fluoroalkyl), a pyrazolate (such as pyrazolate 13, where each R is independently selected from H, alkyl, and fluoroalkyl), a beta-aminoalkoxide (such as betaaminoalkoxide 14, where each R is independently selected from H, alkyl, and fluoroalkyl), or a guandinidate 15 (such as guandinidate 15, where each R is independently selected from H, alkyl, and fluoroalkyl). These are monoanionic ligands that are capable of binding to molybdenum in bidentate manner.

In some embodiments, the at least one organic precursor is a sulfur containing ligand that is capable of forming molybdenum-sulfur bond. In some embodiments the at least one organic ligand in the precursor is a thioether. The term “thioether” is used herein broadly to include to include both unidentate and multidentate (e.g. bidentate or tridentate) thioethers, as well as ligands that contain both thioether and thiolate (or other) moieties. An example of a unidentate thioether is dialkylsulfide R₂S, where each R is an alkyl, such as dimethylsulfide, diethylsulfide, diisobutyl sulfide, and the like. An example of a multidentate thioether ligand that also includes thiolate moieties is (SCH₂CH₂SCH₂CH₂S)²⁻ An example of a monodentate thioether is thioether 18, shown in FIG. 5, where each R is independently selected from the group consisting of alkyl, and fluoroalkyl. In some embodiments each R is independently selected from the group consisting of methyl, ethyl, n-propyl, isopropyl, n-butyl, isobutyl, sec-butyl, and t-butyl.

In some embodiments, the at least one organic ligand is a thiolate, such as a monoanionic thiolate 19, wherein R is an alkyl or fluoroalkyl. For example, R can be methyl, ethyl, n-propyl, isoropyl, n-butyl, sec-butyl, isobutyl, or t-butyl. In some embodiments the thiolate is a dithiolate, such as dianionic alpha-dithiolate 24, (where each R is independently selected from H, alkyl, and fluoroalkyl) or dianionic betadithiolate 25 (where each R is independently selected from H, alkyl, and fluoroalkyl). Dithiolates are capable of forming two molybdenum-sulfur bonds with molybdenum.

In some embodiments, the at least one organic ligand in the precursor is a dithiolene. Examples of dithiolenes are structures 20, 21, and 22, where each R is independently selected from H, alkyl, and fluoroalkyl. This ligand (similarly to DAD) can exist in a neutral form 20, monoanionic radical form 21, and dianionic form 22. Due to redox activity of the monoanionic radical form 21, it can be relatively easily removed during deposition and reduction of molybdenum precursor, making complexes of dithiolene 21 particularly useful for deposition of molybdenum metal and high purity molybdenum metal. Dithiolene ligands 20, 21, and 22 can serve as bidentate ligands, each capable of forming two molybdenum-sulfur bonds. In some embodiments the molybdenum precursor includes dithiolene ligand 20, 21, and/or 22 as an organic ligand, where each R is independently selected from methyl, ethyl, propyl, isopropyl, n-butyl, sec-butyl, isobutyl, and t-butyl.

In some embodiments, the at least one organic ligand in the precursor is an alpha-iminothiolene, such as structure 23, where each R is independently selected from H, alkyl, and fluoroalkyl. In some embodiments each R substituent at the carbon atoms is independently selected from H, alkyl, fluoroalkyl, alkylsilyl, alkylamino, and alkoxy substituents, while R substituent at the nitrogen is independently selected from an alkyl and fluoroalkyl. In some embodiments R substituent at the nitrogen is independently selected from methyl, ethyl, propyl, isopropyl, n-butyl, sec-butyl, isobutyl and t-butyl. This ligand (similarly to DAD, and dithiolene) has a monoanionic radical form, as shown in structure 23, is redox-active, and easily removable during reduction processes.

In some embodiments the precursor is a compound having a formula Mo(X)ₘ(L)ₙ, where m is selected from 1-4, n is selected from 1-3, each X is a halide independently selected from F, Cl, Br, and I and each L is an organic ligand as described above, e.g., a ligand independently selected from amidinates, amidates, iminopyrrolidinates, diazadienes, beta-imino amides, alpha-imino alkoxides, betaamino alkoxides, beta-diketiminates, beta-ketoiminates, beta-diketonates, amines, and pyrazolates, thioethers, thiolates, dithiolenes, dithiolates, and α-imino thiolenes. In some embodiments in the named ligands each R is independently selected from H, alkyl, and fluoroalkyl.

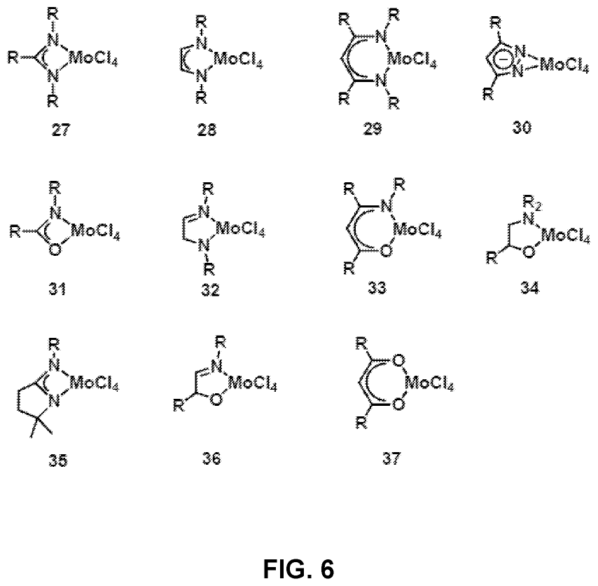

In some embodiments L is a bidentate ligand. Examples of suitable molybdenum-containing precursors of formula Mo(L)Cl₄, that utilize bidentate ligands are shown in FIG. 6. These are Mo(V) compounds and include an amidinate molybdenum complex 27, a DAD complex 28, a beta-diketiminate complex 29, a pyrazolate complex 30, an amidate complex 31, a beta-imino amide complex 32, a beta-ketoiminate complex 33, a beta-amino alkoxide complex 34, an iminopyrrolidinate complex 35, an alpha-imino alkoxide complex 36, and a betadiketonate complex 37.

The heteroleptic complexes with molybdenum-halide bonds and organic ligands described herein can be synthesized using a reaction of molybdenum halide starting materials with the compounds comprising organic ligands in neutral or anionic form. For example, molybdenum(V) precursors may be prepared using MoCl₅ as a starting material. Mo(III) precursors may be prepared using MoX₃(THF)₃ as a starting material, where X is selected from chloride, bromide, and iodide, and THF is tetrahydrofuran. The starting materials can be treated with the ligand in a neutral or anionic form (e.g. a salt, such as lithium or sodium salt), to form the heteroleptic complexes described herein.

The heteroleptic molybdenum compounds containing molybdenum-halide bonds and organic ligands described herein can advantageously provide high purity molybdenum metal in CVD-type and ALD-type deposition methods provided herein. Further, the use of these compounds can be associated with reduced etching of the substrate materials as compared with conventional homoleptic molybdenum halides. These advantages are described for illustration purposes and do not limit the use of these compounds solely to molybdenum metal deposition or to deposition on etching-sensitive substrates.

In some embodiments, when deposition is conducted on fluorine-sensitive materials (e.g., silicon-containing materials) the precursors are selected to be fluorine free, e.g., include any of the Cl, Br, and I as the halides in the complex. Further, the use of compounds with fluoroalkyl substituents may be avoided in these embodiments.

### Sulfur-Containing Molybdenum Compounds

In one aspect, sulfur-containing molybdenum compounds are used as molybdenum-containing precursors for deposition of molybdenum-containing films, such as for deposition of molybdenum metal and molybdenum silicide. In some embodiments, the molybdenum compounds include molybdenum, and at least one sulfur-containing ligand providing molybdenum-sulfur bonding. Molybdenum precursors which are based on sulfur-containing ligands can be used to deposit molybdenum-containing films which are substantially free of impurities due to the ease of removal of sulfur impurities compared to oxygen, carbon, and nitrogen impurities. In some embodiments, the molybdenum compounds do not include molybdenum-carbon bonds and/or do not include molybdenum-oxygen double bonds.

In some embodiments the molybdenum compounds do not include molybdenum-nitrogen double bonds. In some embodiments in the provided molybdenum precursors molybdenum forms bonds only with sulfur atoms.

Examples of suitable sulfur-containing ligands that provide sulfur bonding include thioethers, thiolates, dithiolenes, dithiolates, thiocarbamates, and α-imino thiolenes. The ligands can include one or more substituents independently selected from the group consisting of H, alkyl, fluoroalkyl, alkylsilyl, alkylamino, and alkoxy substituents. The ligands can be neutral or anionic (e.g., monoanionic or dianionic), and molybdenum can be in a variety of oxidation states, such as 0, +1, +2, +3, +4, +5, 10 and +6.

In some embodiments the sulfur-containing ligands are ligands 18-25 shown in FIG. 5, where R substituents are as previously described. Examples of suitable molybdenum precursors include molybdenum thiolates Mo(SR)₄, wherein R is an alkyl, e.g., methyl, ethyl propyl, butyl. In one specific example, the precursor is tetrakis(tert-butylthiolato)molybdenum(IV): Mo(SR)₄, wherein R is t-butyl. Another example of suitable molybdenum precursors are molybdenum thiocarbamates, such as tetrakis(diethyldithiocarbamato)molybdenum(IV):

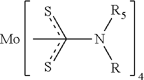

where each R is independently selected from alkyl (e.g., ethyl, methyl, propyl, butyl), and fluoroalkyl (e.g., CF₃). In one specific example the precursor is tetrakis(diethyldithiocarbamato)molybdenum(IV).

In some embodiments dithiolene complexes of molybdenum are provided, where dithiolene may be in any of a neutral form 20, anion-radical form 21, and dianionic form 22, where each R is independently H, alkyl or fluoroalkyl.

Dithiolene complexes are redox-active and can support molybdenum in a variety of oxidation states. Redox reactions of dithiolene ligands 20, 21, and 22 are shown in Equation 1:

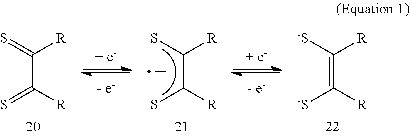

In one implementation, the precursor is Mo(21)₃, where each R in 21 is independently selected from H, alkyl, and fluoroalkyl. For example, R may be methyl, ethyl, CF₃, etc. This is a homoleptic Mo(III) compound containing exclusively molybdenum-sulfur bonds.

In some embodiments, the ligands may provide nitrogen bonding in addition to sulfur bonding. One example of such ligand is alpha-iminothiolene 23, which is a redox-active radical anion ligand that can exhibit behavior similar to that of thiolenes.

In some embodiments the precursor is Mo(III) compound Mo(23)₃, where each R in 10 compound 23 is independently selected from H, alkyl, and fluoroalkyl.

In some embodiments, the precursor is MoLₙ compound, where n is from 2 to 6, and L is a sulfur-containing ligand, such as any of the sulfur-containing ligands described herein. In some embodiments each L is the same sulfur-containing ligand. In other embodiments the precursor may include different sulfur containing ligands L. Examples of precursors include Mo(19)₂, Mo(19)₃, Mo(19)₄, Mo(19)₅, Mo(19)₆, Mo(19)₂(18)₂, Mo(19)₃(18), Mo(19)₄(18)₂, Mo(21)₃, Mo(20)(21)₂, Mo(22)₃, Mo(21)(22)₂, Mo(20)(22)₂, Mo(23)₃, Mo(24)₃, Mo(25)₃. The sulfur-containing molybdenum compounds described herein can be synthesized using a reaction of molybdenum halide starting materials with the compounds comprising organic sulfur-containing ligands in neutral or anionic form. For example, molybdenum(V) precursors may be prepared using MoCl₅ as a starting material. Mo(III) or Mo(IV) precursors may be prepared using corresponding halides or MoX₃(L)₃ or MoX₄(L)₂ as a starting material, where X is selected from chloride, bromide, and iodide, and L is a neutral Lewis base such as tetrahydrofuran or diethyl ether. The starting materials can be treated with the desired sulfur-containing ligand in a neutral or anionic form (e.g. a salt, such as lithium or sodium salt), to form the sulfur-containing complexes described herein.

In one example, Mo(IV) thiolato complexes are prepared by reacting molybdenum tetrachloride with lithium thiolates. For example MoCl₄ can be reacted with t-BuSLi in 1,2-dimethoxythane solvent to form Mo(t-BuS)₄ compound.

α-Iminothiolene ligands can be prepared from the corresponding α-iminoketone by thionation using a suitable reagent such as Lawesson's reagent. The radical anionic form of the α-iminothiolene can be prepared subsequently by treatment with an alkali metal, such as lithium. The resulting ligands and ligand salts can be reacted with molybdenum halides to form α-iminothiolene-containing molybdenum compounds.

Molybdenum complexes can also be prepared using compounds, where molybdenum is in a zero oxidation state, such as molybdenum hexacarbonyl. The starting material can be treated with a neutral ligand, such as a thioether (dialkylsulfide), to induce redox neutral ligand exchange. The zero valent starting material can also be treated with a ligand precursor, such as bis(diethylthiocarbamoyl)disulfide or bis(trifluoromethyl)-1,2-dithiete, to induce oxidative addition and form the sulfur-containing complexes described herein.

The reactions may be conducted in a variety of non-protic solvents. For example the reaction may be conducted in an ether solvent, such as tetrahydrofuran, 2-methyltetrahydrofuran, diethyl ether, methyl-tert-butyl ether, 1,2-dimethoxyethane, in a hydrocarbon solvent such as toluene, benzene, heptane, hexane, pentane, or in a halocarbon solvent such as chlorobenzene, dichlorobenzene, fluorobenzene, difluorobenzene, dichloromethane, chloroform, etc. The reactions can be conducted in a wide temperature range depending on the boiling point of the solvent and on solubility of the products. In some embodiments, the starting materials, reaction intermediates, and the desired products are unstable toward moisture and oxygen. Accordingly, the reaction

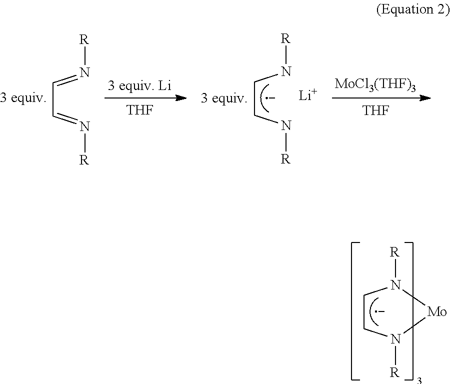

process should be conducted using anhydrous and air-free conditions using a protective inert gas, such as nitrogen or argon.

### 1,4-Diazabutadiene (DAD) Containing Precursors

In another aspect, DAD-containing molybdenum-containing precursors are provided. DAD can bind to molybdenum in its neutral form 5, in its radical-anionic form 6, and in its dianionic form 7. In some embodiments, homoleptic DAD complexes are provided of formula Mo(DAD)m, where m is from 1 to 3, and each DAD is independently selected from neutral DAD 5, radical-anionic DAD 6, and dianionic DAD 7. The oxidation state of molybdenum in these complexes can range from 0 to +6. Non-limiting examples of suitable homoleptic DAD complexes include tris-DAD Mo(III) precursor Mo(6)₃, bis-DAD Mo(IV) precursor Mo(7)₂, bis-DAD Mo(III) precursor Mo(6)(7), and bis-DAD Mo(II) precursor Mo(6)₂.

In some embodiments homoleptic DAD complexes are prepared using a reaction between molybdenum halide and a source of DAD ligand in the required electronic configuration. For example, tris-DAD Mo(III) precursor Mo(6)₃ can be synthesized by reacting MoCl₃ with three equivalents of the radical anion form of the DAD ligand, which can be prepared from the neutral form of the DAD ligand by treatment with an alkali metal, such as lithium, in a solvent, such as THF, as shown in Equation 2.

In some embodiments, heteroleptic DAD-containing molybdenum compounds are provided. In some implementations the precursor includes molybdenum, at least one DAD ligand bound to molybdenum, and at least one second ligand, wherein the DAD may be neutral DAD 6, radical anionic DAD 7, or dianionic DAD 8, and the second ligand is independently selected from anionic ligands and neutral ligands. In some embodiments the precursor does not contain CO ligands as the only second ligands. In some embodiments the precursor is Mo(DAD)ₘ(L)ₙ(X)ₚ, where L is a neutral Lewis base ligand and each L is independently selected from CO, an amine, a phosphine, a thioether, a nitrile, and an isonitrile, and X is an anionic ligand, and each X is independently selected from a halide, an alkyl, an allyl, and a cyclopentadienyl, and m is 1-3, n is 0-4, and p is 0-4. Nitriles are RCN compounds, where R is an alkyl. Isonitriles are RNC compounds, where R is an alkyl. Other suitable anionic ligands include alkoxides, amides, imides, and any other anionic ligands that include a donor atom chosen from C, N, O, B, S, Si, Al, and P.

Examples of heteroleptic DAD-containing precursors include without limitation Mo(7)₂(RCN)Cl, Mo(7)₂(RNC)Cl, Mo(8)(CO)₃, Mo(6)(13)Cl, Mo(6)(18)Cl₂, Mo(6)₂Cl, Mo(6)₂(14), Mo(6)₂(19), Mo(6)₂(24).

Heteroleptic DAD-containing precursors can be prepared by sequential salt metathesis reactions in one pot or using multiple steps. Molybdenum halide starting materials such as Mo(V), Mo(IV), or Mo(III) halides can be treated with anionic forms of a DAD ligand or other anionic ligands. Neutral Lewis base ligands can be exchanged using thermal treatment or photoexcitation.

Heteroleptic DAD-containing precursors can also be prepared using a zero valent molybdenum starting material, such as molybdenum hexacarbonyl, which can undergo oxidative addition with redox active ligands, such as DAD ligands.

In some embodiments, the precursors containing radical anionic DAD ligand 8 are particularly preferred for deposition of molybdenum metal and high purity molybdenum metal. In the radical anionic form 7, the DAD ligand is electronically coupled to vacant molybdenum d-orbitals and is believed to serve as a source of electrons which reduce the molybdenum ions to the zerovalent metallic state. After ligand-to-metal electron transfer, the volatile, neutral DAD ligand 6 can be purged away from the molybdenum metal growth surface. Since the DAD ligand can be removed intact from the growth surface, incorporation of impurity elements such as C and N are reduced when using DAD precursors as compared to other metalorganic precursors. Therefore, molybdenum precursors containing radical anionic DAD ligands can be used for depositing high purity molybdenum metal at low temperatures.

### Di-Molybdenum Precursors

In another aspect, precursors for deposition of molybdenum-containing films are di-molybdenum compounds containing a molybdenum-molybdenum bond (e.g., a multiple molybdenum-molybdenum bond, such as a double bond, or any multiple bond with a bond order of 2-5). Such precursors are particularly useful for deposition of molybdenum metal and high purity molybdenum metal because it is easier to reduce such compounds to metallic molybdenum than many mononuclear molybdenum compounds.

In some embodiments, a precursor for deposition of molybdenum-containing films is provided, wherein the precursor is Mo₂Lₙ, wherein each L is independently selected from amidate, amidinate, and guanidinate ligands, n is 2-5, and where the precursor includes a multiple molybdenum-molybdenum bond. In some embodiments each L is independently selected from an amidinate ligand 2, amidate ligand 3, and a guanidinate ligand 15, wherein each R in the amidinate, amidate, and guanidinate is independently selected from H, alkyl, fluoroalkyl, alkylsilyl, alkylamino, and alkoxy substituents. In some embodiments each R is independently selected from H, alkyl, and fluoroalkyl. In some embodiments each L is an amidinate and the precursor has a formula Mo₂(L)₃ or Mo₂(L)₄. In some embodiments each L is an amidinate and the precursor has a formula Mo₂(L)₃ or Mo₂(L)₄. In some embodiments each L is a guanidinate and the precursor has a formula Mo₂(L)₃ or Mo₂(L)₄. In these complexes molybdenum has a low oxidation state 2+(in Mo₂(L)₃) and 3+ in (Mo₂(L)₄) making these complexes particularly suitable for facile reduction to molybdenum metal.

One exemplary structure of an amidate paddlewheel di-Mo (II) precursor having a quadruple molybdenum-molybdenum bond is shown by structure 38:

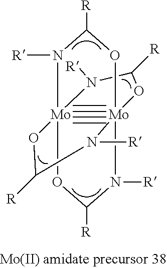

In some embodiments each of R and R′ is independently selected from alkyls, such as methyl, ethyl, isopropyl, and t-butyl. In some embodiments one, two, three or four amidate ligands in 38 may be substituted by amidinate or guanidinidate ligands.

Di-molybdenum precursors described herein can be synthesized using dimolybdenum tetraacetate as a starting material by treatment with a ligand salt such as lithium amidate.

### Cobalt Precursors

Cobalt metal can be deposited using a variety of cobalt precursors, where cobalt may be in +1, +2 or +3 oxidation states. Examples of cobalt precursors include cobalt acetate, cobalt acetylacetonates (e.g., cobalt (III) bis(acetylacetonate)), cobalt amidinates (e.g., bis(N-t-butyl-N′-ethylpropanimidamidato)cobalt(II),) cobaltocene, and carbonyl-containing cobalt precursors (e.g., cobalt tricarbonyl nitrosyl, and cyclopentadienylcobalt dicarbonyl). An example of a halogen-containing cobalt precursor is CoCl₂(TMEDA), where TMEDA is N,N,N′,N′tetramethylethylenediamine.

### Ruthenium Precursors

Ruthenium metal can be deposited, for example, using vaporizable ruthenium precursors, such as bis(ethylcyclopentadienyl)ruthenium(II), bis(pentamethylcyclopentadienyl)ruthenium, ruthenocene, and cyclopentadienylpropylcyclopentadienylruthenium(I).

### Tungsten Precursors

Tungsten can be deposited using a variety of volatile precursors. In some embodiments halogen-containing tungsten precursors, such as WHalₓ, where Hal is a halogen (e.g., F, Cl, Br, and/or I) and x is from 2 to 6, are used. In some embodiments tungsten chloride is used. Tungsten chloride includes tungsten pentachloride (WCl₅), tungsten hexachloride (WCl₆), tungsten tetrachloride (WCl₄), tungsten dichloride (WCl₂), and mixtures thereof. In other examples tungsten fluoride, such as tungsten hexafluoride may be used.

### Additional Precursors

In some embodiments, other useful precursors include vanadium-containing precursors such as tetrakis(dimethylamino)vanadium, tris(dimethylamino)cyclopentadienylvanadium, tetrakis(ethylmethylamino)vanadium; niobium-containing precursors such as (tert-butylimido)bis(diethylamino)niobium, (tert-butylimido)bis(dimethylamino)niobium and (tert-butylimido)bis(ethylmethylamino)niobium; tantalum-containing precursors such as tert-butylimidotris(dimethylamido)tantalum and tantalum pentachloride; iron-containing precursors such as iron (III) tert-butoxide dimer, ferrocene and iron pentcarbonyl; nickel-containing precursors such as allyl(cyclopentadienyl)nickel(II) and nickel(II) bis(acetylacetonate); zinc-containing precursors such as zinc acetate and diethylzinc; and chromium-containing precursors such as chromium carbonyl and bis(cyclopentadienyl)chromium (II).

Returning to FIG. 1, prior to operation 102, the substrate may be optionally pre-treated with a plasma of a hydrogen-containing gas source. The pre-treatment optionally also includes an oxygen-containing gas source. Typically, process conditions for pre-treatment are similar to the conditions utilized for contacting reactants with the substrate.

In an operation 104, the deposition chamber is optionally purged after introduction of the metal precursor. Purge or carrier gases are selected to be non-reactive with the process gas (the reactant) and volatile byproducts. Gases such as helium, argon, nitrogen and combinations thereof may be used. In some embodiments, purging may consist of flowing a total of 1-20 slm or 1-40 slm of an inert gas such as argon or helium.

Purging is done at a high flow rate, depending upon the geometry of the chamber and pressure. In some embodiments, the purge gas may also include hydrogen. Purge pressures may be selected to preserve an isobaric process flow e.g. dose/purge/plasma/purge all at one pressure. In one embodiment, the pressure may be about 1 to about 1.5 Torr, but may extend up to about 10 Torr or higher. Purge times are from about one to about 20 seconds. Wafer temperature is held constant during the operation.

In an operation 106, the surface of the substrate is exposed to a plasma of a hydrogen-containing gas source (the reactant). The pretreatment step, 102, may have similar conditions to operation 106, but is typically much longer. Alternatively, it may be different than operation 106, depending on the incoming substrate and what is being cleaned off it in step 102.

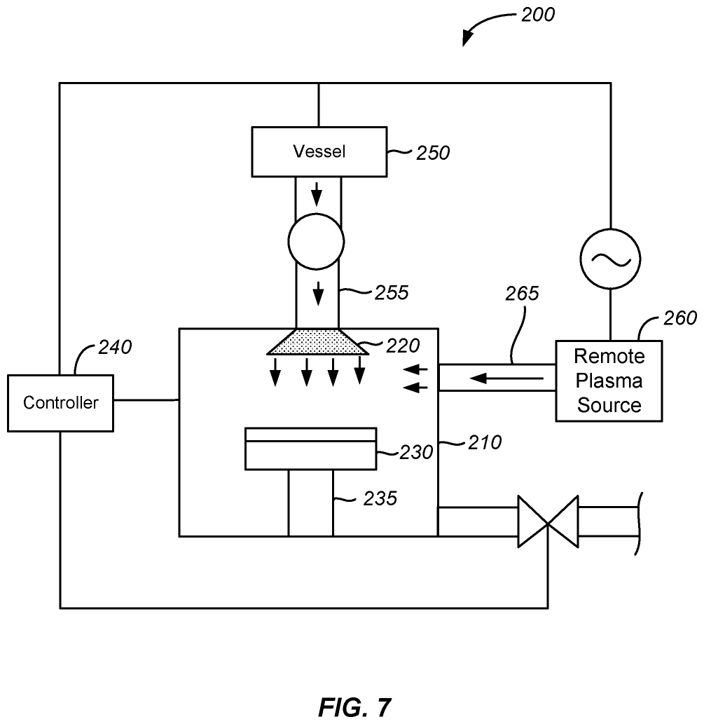

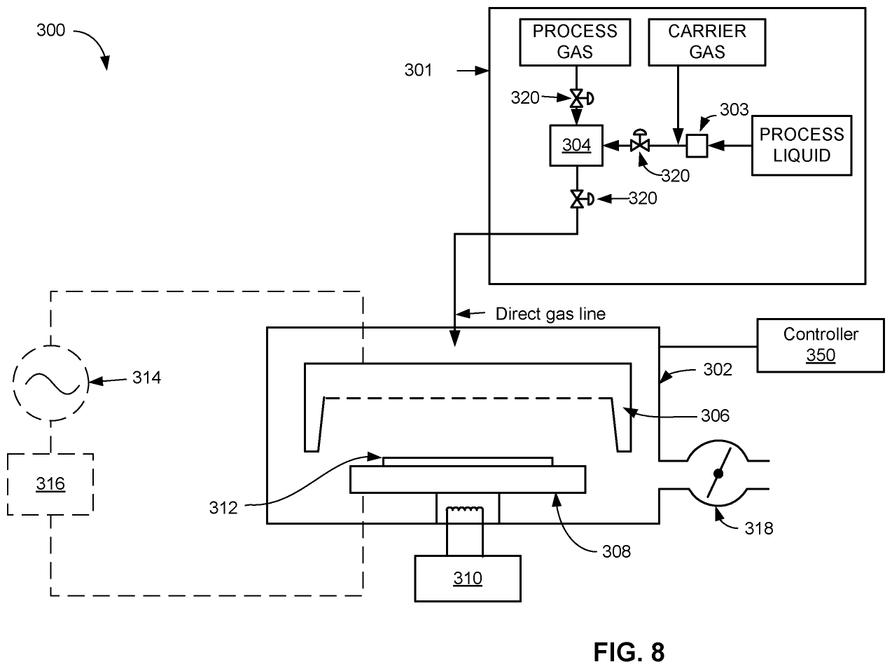

Direct plasma conditions sometimes employed in PEALD can lead to directionality in the deposition because the energy to break up the precursor molecules can be a low frequency which creates a lot of ion bombardment at the surface. The directional deposition can also lead to deposition of films with poor step coverage. A direct plasma (or plasma generated directly) is a plasma in which the plasma (electrons, neutral species, radicals, and positive ions at an appropriate concentration) resides in close proximity to the substrate surface during deposition, sometimes separated from the substrate surface by only a plasma sheath. Ions can play an important role in the direct plasma process. An apparatus for direct plasma treatment is described in FIG. 8 below. In some embodiments, the plasma is generated remotely. A remote plasma (or plasma generated remotely) is one in which the plasma is generated at a distance from the substrate. The major reaction species may be radicals for plasma generated remotely. An apparatus for direct plasma treatment is described in FIG. 7 below. Under some circumstances, there may be certain advantages of using a remote plasma instead of a direct plasma.

In some embodiments, a plasma of reactive species is formed. The plasma species could include electrons, positive ions, neutral species, radicals, and other plasma species. In some embodiments, the plasma may be a hydrogen-based plasma as the hydrogen-containing source including hydrogen atoms, hydrogen radicals, hydrogen reactive species, hydrogen plasma or combinations thereof. The plasma may be an oxygen-based plasma as the oxygen-containing source including oxygen atoms, oxygen radicals, oxygen reactive species, oxygen plasma or combinations thereof. In some embodiments, the plasma may also comprise noble gas species, for example argon, neon, krypton, xenon or helium species. In some instances, the plasma may comprise other species, for example, nitrogen atoms, nitrogen radicals, nitrogen plasma or combinations thereof.

In some embodiments the substrate is contacted with a reactant comprising hydrogen, oxygen, and helium plasma. The plasma may be formed in a reaction chamber or upstream of a reaction chamber, for example by flowing the hydrogen, oxygen and helium through a remote plasma generator, thereby generating plasma species that are introduced downstream to the reaction chamber. Alternatively, hydrogen and helium plasma may be fed into a reaction chamber separately from oxygen and helium plasma. In some embodiments, the hydrogen gas is supplied in a volume of from about 500 to about 5000 sccm (standard cubic centimeters/minute/one station chamber). In some embodiments of the plasma pre-treatment, the oxygen gas is supplied in a volume of from about 1 to about 150 sccm. In some embodiments, the oxygen gas is supplied in a volume of from about 15 to about 100 sccm. In some embodiments of the plasma pre-treatment, the helium gas is supplied in a volume of from about 1000 to about 10,000 sccm. In some embodiments, helium may be omitted. In some embodiments, another inert gas may be used instead of or in addition to helium.

One cycle of process 100 may be operations 102 and 106, or optionally additionally include one or both purge operations 104 and 108.

In an operation 108, the deposition chamber may optionally be purged again.

In an operation 110, if the desired thickness is achieved, the process can be ended.

The desired thickness may range from about less than 1 nm to about 50 nm, depending upon the application. If the desired thickness hasn't yet been achieved, the process operations 102-108 repeat for the number of cycles sufficient to achieve the desired metal thickness.

The Apparatus with Remote Plasma Generator

One aspect of the disclosure is an apparatus configured to accomplish the methods described herein. A suitable apparatus includes hardware for accomplishing the process operations and a system controller having instructions for controlling process operations in accordance with the present disclosure. In some embodiments, the apparatus for performing the aforementioned process operations can include a remote plasma source. A remote plasma source may be preferable over a direct plasma source under certain circumstances, as it may provide mild reaction conditions in comparison to a direct plasma.

FIG. 7 presents a schematic diagram of a remote plasma apparatus according to certain embodiments. The device 200 includes a reaction chamber 210 with a showerhead assembly 220. Inside the reaction chamber 210, a substrate 230 rests on a stage or pedestal 235. In some embodiments, the pedestal 235 can be fitted with a heating/cooling element. A controller 240 may be connected to the components of the device 200 to control the operation of the device 200. For example, the controller 240 may contain instructions for controlling process conditions for the operations of the device 200, such as the temperature process conditions and/or the pressure process conditions. In some embodiments, the controller 240 may contain instructions for controlling the flow rates of precursor gas, co-reactant gas, source gas, and carrier gas. The controller 240 may contain instructions for changing the flow rate of the co-reactant gas over time. In addition, or in the alternative, the controller 240 may contain instructions for changing the flow rate of the precursor gas over time.

During operation, gases or gas mixtures are introduced into the reaction chamber 210 via one or more gas inlets coupled to the reaction chamber 210. In some embodiments, two or more gas inlets are coupled to the reaction chamber 210. A first gas inlet 255 can be coupled to the reaction chamber 210 and connected to a vessel 250, and a second gas inlet 265 can be coupled to the reaction chamber 210 and connected to a remote plasma source 260. In embodiments including remote plasma configurations, the delivery lines for the precursors and the radical species generated in the remote plasma source are separated. Hence, the precursors and the radical species do not substantially interact before reaching the substrate 230.

One or more radical species may be generated in the remote plasma source 260 and configured to enter the reaction chamber 210 via the gas inlet 265. Any type of plasma source may be used in remote plasma source 260 to create the radical species. This includes, but is not limited to, capacitively coupled plasmas, inductively coupled plasmas, microwave plasmas, DC plasmas, and laser-created plasmas. An example of a capacitively coupled plasma can be a radio frequency (RF) plasma. A high-frequency plasma can be configured to operate at 13.56 MHz or higher. Another example of such a RF remote plasma source 260 may be one which can be operated at 440 kHz and can be provided as a subunit bolted onto a larger apparatus for processing one or more substrates in parallel. In some embodiments, a microwave plasma can be used as the remote plasma source 260. A microwave plasma can be configured to operate at a frequency of 2.45 GHz. Gas provided to the remote plasma source may include hydrogen, nitrogen, oxygen, and other gases as mentioned elsewhere herein. In certain embodiments, hydrogen is provided in a carrier such helium. As an example, hydrogen gas may be provided in a helium carrier at a concentration of about 1-10% hydrogen.

The precursors can be provided in vessel 250 and can be supplied to the showerhead 220 via the first gas inlet 255. The showerhead 220 distributes the precursors into the reaction chamber 210 toward the substrate 230. The substrate 230 can be located beneath the showerhead 220. It will be appreciated that the showerhead 220 can have any suitable shape, and may have any number and arrangement of ports for distributing gases to the substrate 230. The precursors can be supplied to the showerhead 220 and ultimately to the substrate 230 at a controlled flow rate.

The one or more radical species formed in the remote plasma source 260 can be carried in the gas phase toward the substrate 230. The one or more radical species can flow through a second gas inlet 265 into the reaction chamber 210. It will be understood that the second gas inlet 265 need not be transverse to the surface of the substrate 230. In certain embodiments, the second gas inlet 265 can be directly above the substrate 230 or in other locations. The distance between the remote plasma source 260 and the reaction chamber 210 can be configured to provide mild reactive conditions such that the ionized species generated in the remote plasma source 260 are substantially neutralized, but at least some radical species in substantially low energy states remain in the environment adjacent to the substrate 230. Such low energy state radical species are not recombined to form stable compounds. The distance between the remote plasma source 260 and the reaction chamber 210 can be a function of the aggressiveness of the plasma (e.g., determined in part by the source RF power level), the density of gas in the plasma (e.g., if there's a high concentration of hydrogen atoms, a significant fraction of them may recombine to form H₂ before reaching the reaction chamber 210), and other factors. In some embodiments, the distance between the remote plasma source 260 and the reaction chamber 210 can be between about 1 cm and 30 cm, such as about 5 cm or about 15 cm.

In some embodiments, a co-reactant, which is not the primary metal-containing precursor or a hydrogen radical, is introduced during the deposition reaction. In some implementations, the apparatus is configured to introduce the co-reactant through the second gas inlet 265, in which case the co-reactant is at least partially converted to plasma. In some implementations, the apparatus is configured to introduce the co-reactant through the showerhead 220 via the first gas inlet 255. Examples of the co-reactant include oxygen, nitrogen, ammonia, carbon dioxide, carbon monoxide, and the like. The flow rate of the co-reactant can vary over time to produce a composition gradient in a graded film.

The controller 240 may contain instructions for controlling process conditions for the operation of the device 200. The controller 240 will typically include one or more memory devices and one or more processors. The processor may include a CPU or computer, analog and/or digital input/output connections, stepper motor controller boards, etc. Instructions for implementing appropriate control operations are executed on the processor. These instructions may be stored on the memory devices associated with the controller 240 or they may be provided over a network.

In certain embodiments, the controller 240 controls all or most activities of the semiconductor processing device 200 described herein. For example, the controller 240 may control all or most activities of the semiconductor processing device 200 associated with depositing a graded silicon carbide film and, optionally, other operations in a fabrication flow that includes the graded silicon carbide films. The controller 240 may execute system control software including sets of instructions for controlling the timing, gas composition, gas flow rates, chamber pressure, chamber temperature, RF power levels, substrate position, and/or other parameters. Other computer programs, scripts, or routines stored on memory devices associated with the controller 340 may be employed in some embodiments. To provide relatively mild reactive conditions at the environment adjacent to the substrate 230, parameters such as the RF power levels, gas flow rate to the remote plasma region, and timing of the plasma ignition can be adjusted and maintained by controller 240. Additionally, adjusting the substrate position may further reduce the presence of high-energy radical species at the environment adjacent to the substrate 230. In a multi-station reactor, the controller 240 may comprise different or identical instructions for different apparatus stations, thus allowing the apparatus stations to operate either independently or synchronously.

In some embodiments, the controller 240 may include instructions for performing operations such as flowing a metal-containing precursor through the first gas inlet 255 into the reaction chamber 210, providing one or more radical species of a source gas in a substantially low energy state from the remote plasma source 260, flowing a co-reactant gas through the second gas inlet 265 into the reaction chamber 210, changing a flow rate of the co-reactant gas over time, and flowing the one or more radical species through the second gas inlet 265 into the reaction chamber 210 to react with the metal-containing precursor to form the thin metal film on the substrate 230. In some implementations, the controller 240 may include instructions for changing a flow rate of the metal-containing precursor over time

In some embodiments, the apparatus may include a user interface associated with controller 240. The user interface may include a display screen, graphical software displays of the apparatus and/or process conditions, and user input devices such as pointing devices, keyboards, touch screens, microphones, etc.

The computer program code for controlling the above operations can be written in any conventional computer readable programming language: for example, assembly language, C, C++, Pascal, Fortran, or others. Compiled object code or script is executed by the processor to perform the tasks identified in the program.

Signals for monitoring the process may be provided by analog and/or digital input connections of the system controller. The signals for controlling the process are output on the analog and digital output connections of the processing system.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In general, the methods described herein can be performed on systems including semiconductor processing equipment such as a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. In general, the electronics are referred to as the controller, which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials (e.g., silicon carbide), surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

In addition to the metal deposition described herein, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The Apparatus with Direct Plasma Generator

FIG. 8 is a schematic diagram of an example plasma processing apparatus for depositing a metal film using thermal ALD according to some implementations. The plasma apparatus or process station 300 includes a plasma processing chamber 302 for maintaining a low-pressure environment. A plurality of plasma apparatuses or process stations 300 may be included in a common low-pressure process tool environment. In some implementations, one or more hardware parameters of the plasma apparatus or process station 300 including those discussed in detail below may be adjusted programmatically by one or more system controllers 350. The plasma apparatus or process station 300 can be configured to perform thermal ALD and PEALD, thermal CVD and PEALD, thermal ALD and PECVD, or thermal CVD and PECVD. In some implementations, the plasma apparatus or process station 300 can be configured to perform one or more PEALD cycles and one or more thermal ALD cycles to deposit a metal film on a substrate 312.

The apparatus or process station 300 fluidly communicates with reactant delivery system 301 for delivering process gases to a distribution showerhead 306. Reactant delivery system 301 includes a mixing vessel 304 for blending and/or conditioning process gases, such as a silicon-containing precursor in the vapor phase, for delivery to showerhead 306. In some implementations, the reactant delivery system 301 includes a mixing vessel 304 for blending and/or conditioning an oxygen-containing reactant (e.g., oxygen) for delivery to the showerhead 306. In some implementations, the reactant delivery system 301 includes a mixing vessel 304 for blending and/or conditioning hydrogen and an oxygen-containing reactant (e.g., oxygen) for delivery to the showerhead 306. One or more mixing vessel inlet valves 320 may control introduction of process gases to mixing vessel 304. Plasma of the oxygen-containing reactant may also be delivered to the showerhead 306 or may be generated in the plasma apparatus or process station 300. The showerhead 306 may be fluidly coupled to the plasma processing chamber 302 for delivery of silicon-containing precursors and reactants into the plasma processing chamber 302.

As an example, the implementation of FIG. 8 includes a vaporization point 303 for vaporizing liquid reactant to be supplied to the mixing vessel 304. In some implementations, vaporization point 303 may be a heated vaporizer. In some implementations, delivery piping downstream of vaporization point 303 may be heat traced. In some examples, the mixing vessel 304 may also be heat traced. In one non-limiting example, piping downstream of vaporization point 303 has an increasing temperature profile extending from approximately 100° C. to approximately 150° C. at the mixing vessel 304. In some implementations, liquid precursor or liquid reactant may be vaporized at a liquid injector. For example, a liquid injector may inject pulses of a liquid reactant into a carrier gas stream upstream of the mixing vessel 304. In one implementation, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 303. In one scenario, a liquid injector may be mounted directly to mixing vessel 304. In another scenario, a liquid injector may be mounted directly to showerhead 306.

In some implementations, a liquid flow controller (LFC) upstream of vaporization point 303 may be provided for controlling a mass flow of liquid for vaporization and delivery to the plasma apparatus or process station 300. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some implementations, the LFC may be dynamically switched between a feedback control mode and a direct control mode. In some implementations, this may be performed by disabling a sense tube of the LFC and the PID controller.

The showerhead 306 distributes process gases toward a substrate 312. In the implementation shown in FIG. 8, the substrate 312 is located beneath the showerhead 306 and is shown resting on a substrate support 308, where the substrate support 308 is configured to support the substrate 312. The substrate support 308 may include a chuck, a fork, or lift pins (not shown) to hold and transfer the substrate 312 during and between the deposition operations. The chuck may be an electrostatic chuck, a mechanical chuck, or various other types of chuck as are available for use in the industry and/or for research. The showerhead 306 may have any suitable shape, and may have any suitable number and arrangement of ports for distributing process gases to the substrate 312.

In some implementations, the substrate support 308 may be raised or lowered to expose the substrate 312 to a volume between the substrate 312 and the showerhead 306. It will be appreciated that, in some implementations, substrate support height may be adjusted programmatically by a suitable system controller 350.

In another scenario, adjusting a height of the substrate support 308 may allow a plasma density to be varied during plasma activation cycles included in the process. At the conclusion of a processing phase, the substrate support 308 may be lowered during another substrate transfer phase to allow removal of the substrate 312 from the substrate support 308.

In some implementations, the substrate support 308 may be configured to be heated to an elevated temperature via a heater 310. In some implementations, the substrate support 308 may be heated to a temperature less than about 700° C., such as about between about 500° C. and about 750° C. or between about 500° C. and about 650° C., during deposition of films as described in the disclosed implementations. Further, in some implementations, pressure control for the apparatus or process station 300 may be provided by a butterfly valve 318. As shown in the implementation of FIG. 8, the butterfly valve 318 throttles a vacuum provided by a downstream vacuum pump (not shown). However, in some implementations, pressure control of the plasma processing chamber 302 may also be adjusted by varying a flow rate of one or more gases introduced to the plasma processing chamber 302. In some implementations, the pressure in the plasma processing chamber 302 may be controlled to be equal to or greater than about 7 Torr, equal to or greater than about 10 Torr, or equal to or greater than about 12 Torr during deposition of silicon oxide films as described in the disclosed implementations.

In some implementations, a position of the showerhead 306 may be adjusted relative to the substrate support 308 to vary a volume between the substrate 312 and the showerhead 306. Further, it will be appreciated that a vertical position of substrate support 308 and/or showerhead 306 may be varied by any suitable mechanism within the scope of the present disclosure. In some implementations, the substrate support 308 may include a rotational axis for rotating an orientation of the substrate 312. It will be appreciated that, in some implementations, one or more of these example adjustments may be performed programmatically by one or more suitable system controllers 350.

In some implementations where plasma may be used as discussed above, showerhead 306 and substrate support 308 electrically communicate with a radio frequency (RF) power supply 314 and matching network 316 for powering a plasma in the plasma processing chamber 302. In some implementations, the plasma energy may be controlled by controlling one or more of a process station pressure, a gas concentration, an RF source power, an RF source frequency, and a plasma power pulse timing. For example, RF power supply 314 and matching network 316 may be operated at any suitable power to form a plasma having a desired composition of radical species. In some implementations, the RF power supply 314 and matching network 316 may be operated to apply plasma power to the plasma processing chamber 302 to ignite plasma generated from hydrogen and oxygen-containing reactant in the plasma processing chamber 302. Example plasma powers applied by the RF power supply 314 may be equal to or less than about 300 W, equal to or less than about 200 W, or between about 10 W and about 200 W. Likewise, RF power supply 314 may provide RF power of any suitable frequency. In some implementations, RF power supply 314 may be configured to control high- and low-frequency RF power sources independently of one another. Example low-frequency RF frequencies may include, but are not limited to, frequencies between 0 kHz and 500 kHz. Example high-frequency RF frequencies may include, but are not limited to, frequencies between 1.8 MHz and 2.45 GHz, or at least about 13.56 MHz, or at least about 27 MHz, or at least about 40 MHz, or at least about 60 MHz. It will be appreciated that any suitable parameters may be modulated discretely or continuously to provide plasma energy for the surface reactions.

In some implementations, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some implementations, one or more plasma parameters may be programmatically adjusted based on measurements from such in situ plasma monitors. For example, an OES sensor may be used in a feedback loop for providing programmatic control of plasma power. It will be appreciated that, in some implementations, other monitors may be used to monitor the plasma and other process characteristics. Such monitors may include, but are not limited to, infrared (IR) monitors, acoustic monitors, and pressure transducers.

In some implementations, instructions for a controller 350 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some implementations, instructions for setting one or more reactor parameters may be included in a recipe phase. For example, a first recipe phase may include instructions for setting a flow rate of an inert and/or a precursor gas (e.g., the silicon-containing precursor), instructions for setting a flow rate of a carrier gas (such as argon), and time delay instructions for the first recipe phase. A second, subsequent recipe phase may include instructions for modulating or stopping a flow rate of an inert and/or a precursor gas, and instructions for modulating a flow rate of a carrier or purge gas and time delay instructions for the second recipe phase. A third recipe phase may include instructions for modulating a flow rate of an oxygen-containing reactant gas such as oxygen, instructions for modulating a flow rate of hydrogen gas, instructions for modulating the flow rate of a carrier or purge gas, and time delay instructions for the third recipe phase. A fourth, subsequent recipe phase may include instructions for modulating or stopping a flow rate of an inert and/or a reactant gas, and instructions for modulating a flow rate of a carrier or purge gas and time delay instructions for the fourth recipe phase. The fourth recipe, in some implementations, may include instructions for igniting plasma of the oxygen-containing reactant. It will be appreciated that these recipe phases may be further subdivided and/or iterated in any suitable way within the scope of the disclosed implementations.

In certain implementations, the controller 350 has instructions to perform the operations described in the present disclosure.

The apparatus/process described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### Example 1

### Copper Deposition

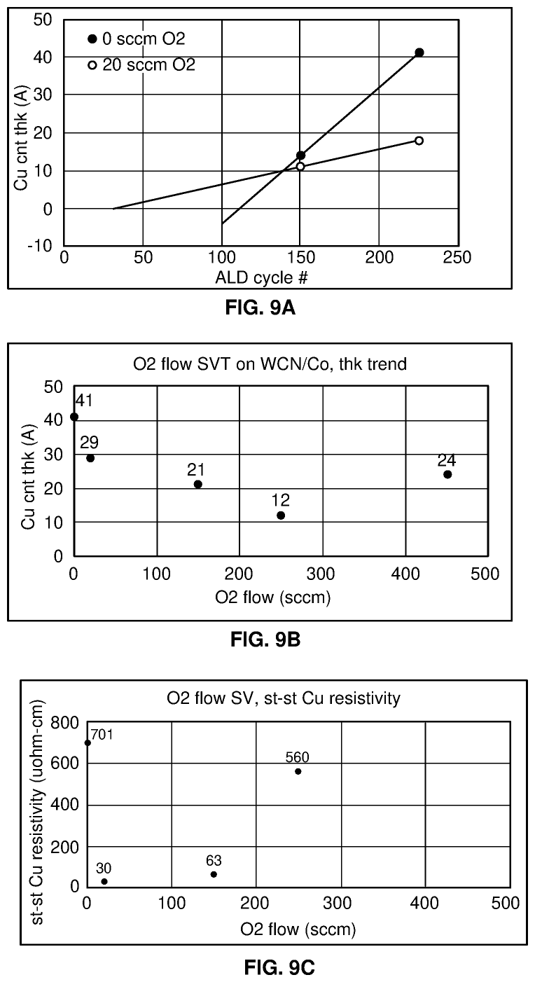

General conditions for the atomic layer deposition method utilized to obtain the results in FIGS. 9A, 9B, 9C, 10, 11A and 11B include use of a copper aminoalkoxide as the copper precursor, 9 slm (standard liter per minute) of helium gas and 3 lm (liters per minute) of hydrogen gas, pressure of less than 10 Torr, and a remote ICP plasma source which is a 13.57 MHz RF generator.

FIG. 9A illustrates an embodiment of the method wherein copper metal thickness can be tuned when oxygen gas is added to the hydrogen gas source in a remote plasma generator. Without added oxygen, a thicker copper layer is deposited as the number of atomic layer deposition cycles increases. With an added oxygen gas at flow rate of 20 sccm, the thickness of the deposition is approximately halved after about 225 cycles.

FIG. 9B provides graphical results for thickness of deposited copper as the oxygen gas flow rate is varied, in an embodiment of the method wherein copper metal thickness is tuned when oxygen gas is added to the hydrogen gas source in a remote plasma generator. As illustrated, a trace amount of oxygen significantly reduces copper thickness.

FIG. 9C provides a graphical plot of the change in copper resistivity as the flow rate of oxygen added to the hydrogen gas source in a remote plasma generator is varied. As shown, a trace amount of oxygen drastically reduces resistivity.

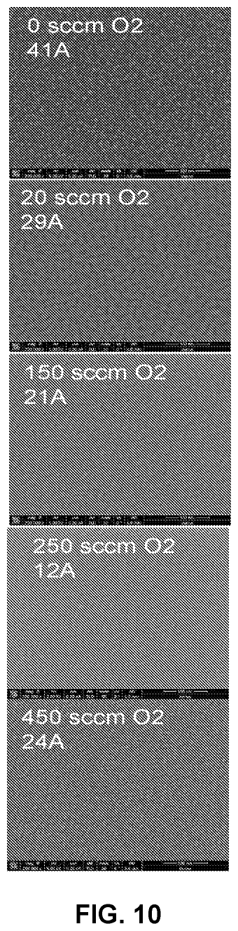

In an embodiment, the addition of oxygen gas to the hydrogen gas source in the remote plasma generator results in changes in the morphology of the deposited copper. As shown in FIG. 10, films deposited in the absence of a trace amount of oxygen gas display rough, discontinuous and island-like morphology. There is a dramatic shift in film morphology upon introduction of 20 sccm of oxygen gas, from islands to interconnected channels. Above 150 sccm of oxygen gas, the morphology becomes island-like once again.

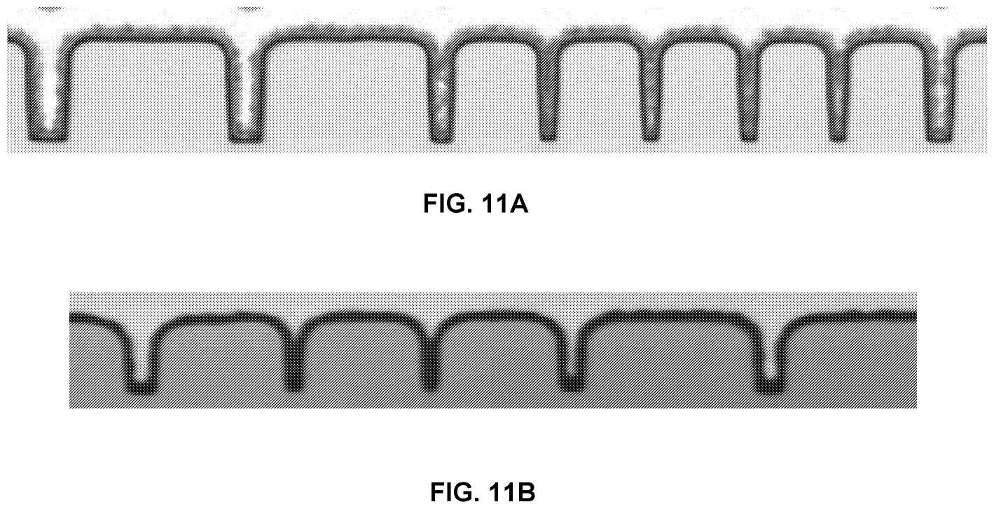

FIG. 11A illustrates copper deposition using a plasma of a hydrogen gas source generated remotely, without addition of oxygen gas. The deposited copper has a rough appearance. FIG. 11B illustrates copper deposition using a plasma of a hydrogen gas source generated remotely when 20 sccm oxygen gas is added to the hydrogen gas source in the remote plasma generator. At this amount of only 0.16% oxygen in the plasma gas flow, the deposition layer has improved morphology with less roughness.

### Example 2

### Molybdenum Deposition

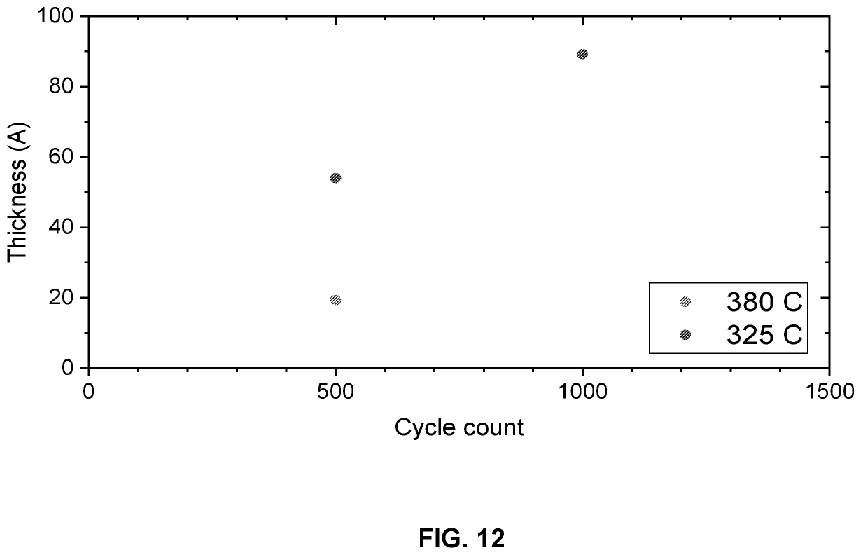

As illustrated in FIG. 12, after 500 cycles of the method under process conditions similar to Example 1 using an MoCl₅ precursor and pre-treatment with a remotely generated plasma of hydrogen, a higher molybdenum metal thickness on a wafer is achieved using the deposition method when the wafer temperature is 270° C. (corresponding to a pedestal temperature of 325° C.) than when the wafer temperature is 310° C. (corresponding to a pedestal temperature of 380° C.).

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method for plasma-enhanced atomic layer deposition of a metal on a substrate comprising:
providing the substrate in a deposition chamber, wherein the substrate is at a temperature of about 300° C. or less;
exposing a surface of the substrate to a vapor phase metal precursor; and
exposing the substrate to plasma generated directly or plasma generated remotely from a hydrogen-containing gas source.

2. The method of claim 1, wherein the metal comprises vanadium, niobium, tantalum, chromium, cobalt, tungsten, iron, ruthenium, nickel, zinc, copper or molybdenum.

3. The method of claim 1, wherein the vapor phase metal precursor comprises vanadium-containing precursors, niobium-containing precursors, tantalum-containing precursors, chromium-containing precursors, cobalt-containing precursors, tungsten-containing precursors, iron-containing precursors, ruthenium-containing precursors, nickel-containing precursors, zinc-containing precursors, copper-containing precursors or molybdenum-containing precursors.

4. The method of claim 1, further comprising pre-treating the surface of the substrate with the plasma generated remotely from the hydrogen-containing gas source before exposing the surface of the substrate to the vapor phase metal precursor.

5. A method for plasma-enhanced atomic layer deposition of molybdenum on a substrate comprising:
providing the substrate in a deposition chamber, wherein the substrate is at a temperature of about 300° C. or less;
exposing a surface of the substrate to a vapor phase molybdenum precursor; and
exposing the substrate to plasma generated directly or plasma generated remotely from a hydrogen-containing gas source.

6. The method of claim 5, wherein the vapor phase molybdenum precursor comprises a structure of formula (I): 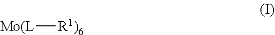
wherein each L is independently O, S or NR²; and
R¹ and R² are independently hydrogen, optionally substituted aliphatic, optionally substituted heteroaliphatic, optionally substituted heteroaromatic, optionally substituted heteroaryl, optionally substituted heterocyclyl, optionally substituted aromatic, optionally substituted aryl, or optionally substituted arylalkylene; and
wherein two R¹ substituents can be taken together to form an optionally substituted cyclic group.

7. The method of claim 5, wherein the vapor phase molybdenum precursor comprises a structure of formula (II): 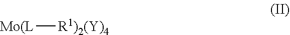
wherein each L is independently O, S, or NR²;
R¹ and R² are independently hydrogen, optionally substituted aliphatic, optionally substituted alkyl, optionally substituted heteroaliphatic, optionally substituted heteroalkyl, optionally substituted heteroaromatic, optionally substituted heteroaryl, optionally substituted heterocyclyl, optionally substituted aromatic, optionally substituted aryl, or optionally substituted arylalkylene; and
wherein two R¹ substituents can be taken together to form an optionally substituted cyclic group; and
each Y is independently chlorine, fluorine, bromine or iodine.

8. The method of claim 5, wherein the vapor phase molybdenum precursor comprises MoCl₅, Mo₂Cl₁₀, MoO₂Cl₂, MoOCl₄ or any combination thereof.

9. The method of claim 5, wherein exposing the surface of the substrate to the vapor phase molybdenum precursor and exposing the substrate to plasma generated remotely from the hydrogen-containing gas source are performed in temporally separate pulses.

10. An apparatus for depositing a thin metal film on a substrate, the apparatus comprising:
at least one reaction chamber including a pedestal for holding the substrate;
at least one inlet port for delivering gas phase metal precursors to the reaction chamber;
a direct plasma generator or a remote plasma generator for providing plasma to the reaction chamber; and
a controller for controlling operations in the apparatus, including machine-readable instructions for
(a) causing the substrate to be at temperature of about 300° C. or less;
(b) causing introduction of a metal precursor in vapor phase into the at least one reaction chamber; and
(c) causing introduction of a plasma from the direct plasma generator or the remote plasma generator to form the thin metal film over the substrate, the plasma generated from a hydrogen-containing gas and from about 0.01% to about 1% of oxygen-containing gas.
